(19) United States
(12) Patent Application Publication
(10) Pub. No.: US 2024/0349511 A1
(43) Pub. Date: Oct. 17, 2024

(54) CAPACITOR AND SEMICONDUCTOR DEVICE INCLUDING THE SAME

(71) Applicant: Samsung Electronics Co., Ltd., Suwon-si (KR)

(72) Inventors: Jungmin PARK, Suwon-si (KR); Ji-Sung KIM, Suwon-si (KR); Han Jin LIM, Suwon-si (KR); Hyungsuk JUNG, Suwon-si (KR)

(73) Assignee: Samsung Electronics Co., Ltd., Suwon-si (KR)

(21) Appl. No.: 18/521,629

(22) Filed: Nov. 28, 2023

(30) Foreign Application Priority Data
Apr. 13, 2023 (KR) 10-2023-0048866

(51) Int. Cl. H10B 53/30; H01G 4/10

(52) U.S. Cl. CPC H10B 53/30; H01G 4/10

(57) ABSTRACT

A capacitor according to at least one embodiment may include a first electrode and a second electrode spaced apart from each other, and a dielectric layer disposed between the first electrode and the second electrode and including a ferroelectric layer and an auxiliary portion disposed in the ferroelectric layer, wherein an energy band gap Eg of the auxiliary portion may be lower than about 4.0 eV.

### CROSS-REFERENCE TO RELATED APPLICATION

This application claims priority to and the benefit of Korean Patent Application No. 10-2023-0048866 filed in the Korean Intellectual Property Office on Apr. 13, 2023, the entire contents of which are incorporated herein by reference.

### BACKGROUND

The present disclosure relates to a capacitor and a semiconductor device including the capacitor.

Recently, research into high-integration memory devices has been actively conducted in manufacturing memory devices.

Dynamic random access memory (DRAM) has a high degree of integration and a fast operating speed, but requires a continuous refresh to store data. In addition, static random access memory (SRAM), electrically erasable programmable read only memory (EEPROM), flash memory, etc. are advantageous for data storage, but require efforts to increase an operating voltage, integration, and an operating speed.

Meanwhile, research into ferroelectric memory devices using ferroelectric capacitors including a ferroelectric dielectric layer has been conducted.

A ferroelectric memory device including a ferroelectric capacitor uses the polarization inversion characteristic of a ferroelectric film and its residual polarization, and is capable of high-speed read/write operations.

However, due to the characteristics of ferroelectric materials, when the read/write operations are performed, ferroelectric characteristics deteriorate over time due to the field induced stresses applied to a dielectric layer, which may causes changes in the ferroelectric characteristics.

### SUMMARY

The present disclosure attempts to provide a capacitor configure to preventing and/or reduce deterioration of ferroelectric characteristics and a semiconductor device including the capacitor.

However, problems to be solved by the embodiments are not limited to the above-described problems and may be extended in various ways within the scope of technical idea included in the embodiments.

A capacitor according to at least one embodiment may include a first electrode and a second electrode spaced apart from each other, and a dielectric layer between the first electrode and the second electrode and including a ferroelectric layer and an auxiliary portion in the ferroelectric layer, wherein an energy band gap of the auxiliary portion may be lower than about 4.0 eV.

The auxiliary portion may include a plurality of auxiliary patterns dispersed in the ferroelectric layer.

The dielectric layer may further include an insulating layer between the ferroelectric layer and at least one of the first and second electrodes, and the insulating layer may include at least one of an antiferroelectric layer or a paraelectric layer.

The auxiliary portion may further include a plurality of atypical first auxiliary patterns dispersed in the insulating layer.

The auxiliary portion may include an auxiliary thin film layer in the ferroelectric layer.

A thickness of the auxiliary thin film layer may be less than a thickness of the ferroelectric layer.

A planar area of the auxiliary thin film layer may be smaller than a planar area of the ferroelectric layer.

The dielectric layer may further include at least two auxiliary thin film layer in the insulating layer.

A ratio of the auxiliary portion of the dielectric layer to a remainder of the dielectric layer may be about 3% to about 10%.

The auxiliary portion may include a metal oxide.

The auxiliary portion may include at least one of zinc oxide (ZnO), tin oxide (SnO₂), indium oxide (In₂O₃), titanium dioxide (TiO₂), tungsten trioxide (WO₃), niobium pentoxide (Nb₂O₅), manganese monoxide (MnO), or nickel oxide (NiO).

A leakage current of the dielectric layer may be 10⁻⁴ A/cm²≤x≤10⁻⁸ A/cm² (e.g., at 1 V).

A thickness of the dielectric layer may be greater than 0 and less than or equal to about 50 Å.

A semiconductor device according to at least one embodiment may include a substrate and a capacitor structure over the substrate, capacitor structure including a plurality of lower electrodes spaced apart from each other in a direction parallel to an upper surface of the substrate, a supporter between the plurality of lower electrodes, and an upper electrode over the plurality of lower electrodes, and a dielectric layer insulating the plurality of lower electrodes from the upper electrode, the dielectric layer including a ferroelectric layer and an auxiliary portion in the ferroelectric layer, wherein an energy band gap of the auxiliary portion may be less than about 4.0 eV.

According to the embodiments, the capacitor configured to prevent (or reduce) deterioration of ferroelectric characteristics and the semiconductor device including the capacitor may be provided.

However, it is obvious that the effects of the embodiments are not limited to the above-mentioned effects, and may be extended in various ways without departing from the spirit and scope of the present disclosure.

### BRIEF DESCRIPTION OF THE DRAWINGS

Embodiments will be more clearly understood from the following detailed description taken in conjunction with the accompanying drawings in which:

FIG. 1 is a cross-sectional view of a capacitor according to at least one embodiment.

FIG. 2 is a cross-sectional view of a capacitor according to at least one embodiment.

FIG. 3 is a cross-sectional view of a capacitor according to at least one embodiment.

FIG. 4 is a cross-sectional view of a capacitor according to at least one embodiment.

FIG. 5 is a cross-sectional view of a capacitor according to at least one embodiment.

FIG. 6 is a cross-sectional view of a capacitor according to at least one embodiment.

FIG. 7 is a cross-sectional view of a capacitor according to at least one embodiment.

FIG. 8 is a cross-sectional view of a capacitor according to at least one embodiment.

FIG. 9 is a cross-sectional view of a capacitor according to at least one embodiment.

FIG. 10 is a cross-sectional view of a capacitor according to at least one embodiment.

FIG. 11 is a cross-sectional view of a capacitor according to at least one embodiment.

FIG. 12 is a cross-sectional view of a capacitor according to at least one embodiment.

FIG. 13 is a cross-sectional view of a capacitor according to at least one embodiment.

FIG. 14 is a cross-sectional view of a capacitor according to at least one embodiment.

FIG. 15 is a cross-sectional view of a capacitor according to at least one embodiment.

FIG. 16 is a diagram for explaining a method of forming a capacitor according to at least one embodiment.

FIG. 17 is a layout diagram of a semiconductor device according to at least one embodiment, and

FIG. 18 is a cross-sectional view taken along line I-I′ of FIG. 17.

### DETAILED DESCRIPTION

Hereinafter, with reference to the accompanying drawings, various embodiments of the present disclosure will be described in detail so that those skilled in the art may easily carry out the present disclosure. The present disclosure may be embodied in many different forms and is not limited to the specific embodiments set forth herein.

In order to clearly explain the embodiments, parts irrelevant to the description are omitted, and the same reference numerals are used for the same or similar elements throughout the specification.

In addition, the accompanying drawings are only for easy understanding of the embodiments disclosed in the present specification, the technical idea disclosed in the present specification is not limited by the accompanying drawings, and should be understood to include all changes, equivalents or substitutes included in the spirit and technical scope of the present disclosure.

In addition, the size and thickness of each component shown in the drawings are shown for convenience of description, and the present disclosure is not necessarily limited to those shown. For example, in the drawings, the thickness of layers, films, panels, regions, etc., are exaggerated for clarity. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. When referring to “C to D”, this means C inclusive to D inclusive unless otherwise specified.

In addition, it will be understood that when an element such as a layer, film, region, or substrate is referred to as being “on” another element, it may be directly on the other element or intervening elements may also be present. In contrast, when an element is referred to as being “directly on” another element, there are no intervening elements present. In addition, being “above” or “on” a reference part means being above or below the reference part, and does not necessarily mean being “above” or “on” in the opposite direction of gravity. Additionally, spatially relative terms, such as “lower,” “upper,” “top,” and/or the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, the device may be otherwise oriented (rotated 90 degrees or at other orientations) and the spatially relative descriptors used herein interpreted accordingly.

In addition, unless explicitly described to the contrary, the word “comprise”, and variations such as “comprises” or “comprising”, will be understood to imply the inclusion of stated elements and not the exclusion of any other elements.

In addition, throughout the specification, when it is “on a plane” means when a target portion is viewed from above, and when it is “on a cross section” means when a cross section obtained by vertically cutting a target portion is viewed from the side.

In addition, throughout the specification, being “connected” does not only mean that two or more elements are directly connected, but may mean that two or more elements are indirectly connected through other elements, physically connected as well as electrically connected, or referred to by different names according to their locations and/or functions.

Hereinafter, various embodiments and modifications will be described in detail with reference to the drawings.

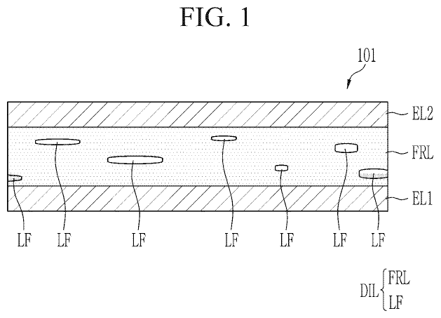

A capacitor 101 according to at least one embodiment is described with reference to FIG. 1. FIG. 1 is a cross-sectional view of a capacitor 101 according to at least one embodiment.

Referring to FIG. 1, the capacitor 101 may include a first electrode EL1 and a second electrode EL2 facing each other and a dielectric layer DIL disposed between the first electrode EL1 and the second electrode EL2.

The first electrode EL1 and the second electrode EL2 each may include a conductive material, such as a metal, a conductive nitride, and/or a conductive oxide. For example, the first electrode EL1 and the second electrode EL2 each may include at least one metal (such as ruthenium (Ru), titanium (Ti), tantalum (Ta), niobium (Nb), iridium (Ir), molybdenum (Mo), tungsten (W), etc.), conductive metal nitride (such as titanium nitride (TiN), tantalum nitride (TaN), niobium nitride (NbN), molybdenum nitride (MoN), tungsten nitride (WN), etc.), and/or conductive metal oxide (such as iridium oxide (IrO₂), ruthenium oxide (RuO₂), strontium ruthenium oxide (SrRuO₃), etc.).

In at least one embodiment, a leakage current (x) of the dielectric layer DIL may be represented by 10⁻⁴ A/cm²≤x≤10⁻⁸ A/cm² (e.g., at 1 V). A thickness of the dielectric layer DIL may be greater than 0 and/or less than or equal to about 50 Å, but the examples are not limited thereto.

The dielectric layer DIL may include a ferroelectric layer FRL and a plurality of auxiliary patterns LF dispersed in the ferroelectric layer FRL.

The ferroelectric layer FRL may include a ferroelectric material having spontaneous polarization. In at least one embodiment, the ferroelectric layer FRL may include at least one of hafnium oxide (HfO₂) and/or lead zirconate titanate (PbZrTi (PZT)). For example, the ferroelectric layer FRL may include hafnium oxide (HfO₂) doped with at least one of silicon (Si), lanthanum (La), yttrium (Y), aluminum (Al), zirconium (Zr), gadolinium (Gd), and/or the like. However, the examples are not limited thereto, and the ferroelectric layer FRL may include other ferroelectric materials.

The auxiliary pattern LF may include a material having E_{g}<4.0 eV. For example, the auxiliary pattern LF may include metal oxide having the energy band gap E_{g} lower than about 4.0 eV. For example, the auxiliary pattern LF may include at least one of zinc oxide (ZnO), tin oxide (SnO₂), indium oxide (In₂O₃), titanium dioxide (TiO₂), tungsten trioxide (WO₃), niobium pentoxide (Nb₂O₅), manganese monoxide (MnO) nickel oxide (NiO), and/or the like.

In at least one embodiment, the plurality of auxiliary patterns LF are dispersed inside the ferroelectric layer FRL, and each of the plurality of auxiliary patterns LF may be a thin film having an atypical form (e.g., there may not be a mean or standard form for the plurality of auxiliary patterns LF). A planar area of each of the plurality of auxiliary patterns LF may be smaller than a planar area of the ferroelectric layer FRL.

A ratio of the plurality of auxiliary patterns LF in the dielectric layer DIL may be in the range of about 3% to about 10%.

Since the ferroelectric layer FRL has ferroelectricity, the ferroelectric layer FRL may maintain an electrical polarization even when an electric field is not applied from the outside.

However, in the case where the ferroelectricity of the ferroelectric layer FRL is strong, when a voltage is applied multiple times and read/write operations are performed repeatedly, stress may be applied to the ferroelectric layer FRL, and a polarization state of the ferroelectric layer FRL is not completely restored to a state before the voltage is applied and remains in a previous polarization state, and, therefore, the performance of the ferroelectric layer FRL may be deteriorated.

According to the capacitor 101, the dielectric layer DIL may include the plurality of auxiliary patterns LF dispersed in the ferroelectric layer FRL, and the auxiliary pattern LF includes the material having the band gap E_{g} lower than about 4.0 eV, and thus, the auxiliary pattern LF may weaken the ferroelectricity of the ferroelectric layer FRL, and accordingly, deterioration in which the polarization state of the ferroelectric layer FRL remains in the previous polarization state without being completely restored to the state before the voltage is applied may be reduced. In addition, the polarization state is maintained without being restored by the ferroelectricity of the ferroelectric layer FRL, thereby reducing the leakage current of the dielectric layer DIL that may occur.

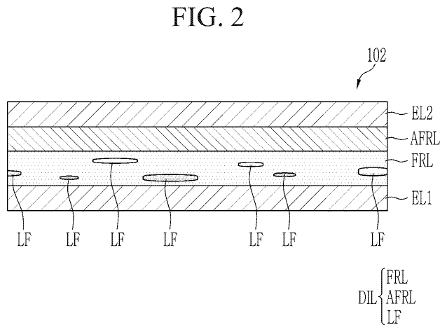

A capacitor 102 according to at least one embodiment is described with reference to FIG. 2. FIG. 2 is a cross-sectional view of a capacitor 102 according to at least one embodiment.

Referring to FIG. 2, detailed descriptions of elements of the capacitor 102 substantially similar to (or the same as) elements of the capacitor 101 may be omitted.

Referring to FIG. 2, the capacitor 102 may include the first electrode EL1 and the second electrode EL2 facing each other and the dielectric layer DIL disposed between the first electrode EL1 and the second electrode EL2.

The first electrode EL1 and the second electrode EL2 each may include a conductive material.

A leakage current of the dielectric layer DIL may be 10⁻⁴ A/cm²≤x≤10⁻⁸ A/cm² (e.g., at 1 V). A thickness of the dielectric layer DIL may be greater than 0 and less than or equal to about 50 Å, but the examples are not limited thereto.

The dielectric layer DIL of the capacitor 102 may include the ferroelectric layer FRL, the plurality of auxiliary patterns LF dispersed in the ferroelectric layer FRL, and an insulating layer AFRL.

The ferroelectric layer FRL and the insulating layer AFRL may overlap each other between the first electrode EL1 and the second electrode EL2. For example, the insulating layer AFRL may be disposed between the ferroelectric layer FRL and at least one of the first electrode EL1 and the second electrode EL2.

The ferroelectric layer FRL may include a ferroelectric material having spontaneous polarization. In at least one embodiment, the ferroelectric layer FRL may include at least one of hafnium oxide (HfO₂) and/or lead zirconate titanate (PbZrTi (PZT)). For example, the ferroelectric layer FRL may include hafnium oxide (HfO₂) doped with at least one of silicon (Si), lanthanum (La), yttrium (Y), aluminum (Al), zirconium (Zr), gadolinium (Gd), and/or the like. However, the examples are not limited thereto, and the ferroelectric layer FRL may include other ferroelectric materials.

The insulating layer AFRL may comprise a material without spontaneous polarization. For example, the insulating layer AFRL may include at least one of an antiferroelectric layer having no spontaneous polarization in which permanent dipoles are arranged in different directions and/or a paraelectric layer in which permanent dipoles do not exist. For example, the insulating layer AFRL may include at least one of zirconium dioxide (ZrO₂), HfₓZr₁₋ₓO₂ (x<0.5), AgNbO₃, and/or the like, but the examples are not limited thereto.

The auxiliary pattern LF may include a material having E_{g}<4.0 eV. For example, the auxiliary pattern LF may include metal oxide having the energy band gap E_{g} lower than about 4.0 eV. For example, the auxiliary pattern LF may include at least one of zinc oxide (ZnO), tin oxide (SnO₂), indium oxide (In₂O₃), titanium dioxide (TiO₂), tungsten trioxide (WO₃), niobium pentoxide (Nb₂O₅), manganese monoxide (MnO), nickel oxide (NiO), and/or the like.

The plurality of auxiliary patterns LF may be dispersed inside the ferroelectric layer FRL, and each may be a thin film having an atypical form. A planar area of each of the plurality of auxiliary patterns LF may be smaller than a planar area of the ferroelectric layer FRL.

For example, a ratio of the plurality of auxiliary patterns LF in the dielectric layer DIL may be about 3% to about 10%.

According to the capacitor 102, the auxiliary pattern LF may weaken the ferroelectricity of the ferroelectric layer FRL, and accordingly, deterioration in which a polarization state of the ferroelectric layer FRL remains in a previous polarization state without being completely restored to a state before a voltage is applied may be reduced (and/or prevented). In addition, the polarization state is maintained without being restored by the ferroelectricity of the ferroelectric layer FRL, thereby reducing the leakage current of the dielectric layer DIL that may occur.

In addition, according to the capacitor 102, the dielectric layer DIL further includes the insulating layer AFRL that overlaps the ferroelectric layer FRL and does not have spontaneous polarization, and thus, overall ferroelectricity within the dielectric layer DIL may be reduced, thereby further reducing (or preventing) deterioration and leakage current of the dielectric layer DIL.

Many features of the capacitor 101 according to the embodiment described above are all applicable to the capacitor 102.

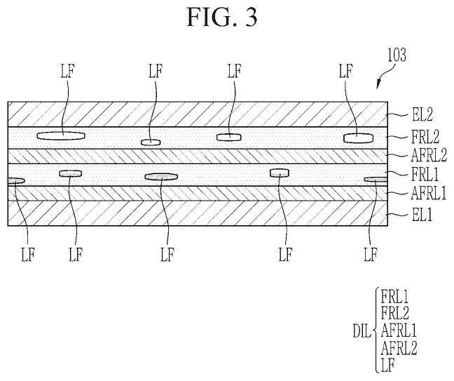

A capacitor 103 according to at least one embodiment is described with reference to FIG. 3. FIG. 3 is a cross-sectional view of a capacitor 103 according to at least one embodiment.

Referring to FIG. 3, detailed descriptions of elements of the capacitor 103 substantially similar to (or the same as) as elements of the capacitors 101 and/or 102 may be omitted.

Referring to FIG. 3, the capacitor 103 may include the first electrode EL1 and the second electrode EL2 facing each other and the dielectric layer DIL disposed between the first electrode EL1 and the second electrode EL2.

The first electrode EL1 and the second electrode EL2 each may include a conductive material.

A leakage current of the dielectric layer DIL may be 10⁻⁴ A/cm²≤x≤10⁻⁸ A/cm² (e.g., at 1 V). A thickness of the dielectric layer DIL may be greater than 0 and less than or equal to about 50 Å, but the examples are not limited thereto.

The dielectric layer DIL of the capacitor 103 may include a plurality of ferroelectric layers FRL1 and FRL2, a plurality of insulating layers AFRL1 and AFRL2, and the plurality of auxiliary patterns LF dispersed in the ferroelectric layers FRL1 and FRL2.

The plurality of ferroelectric layers FRL1 and FRL2 and the plurality of insulating layers AFRL1 and AFRL2 may overlap each other and be alternately disposed between the first and second electrodes EL1 and EL2 facing each other, but the examples are not limited thereto.

The plurality of ferroelectric layers FRL1 and FRL2 each may include a ferroelectric material having spontaneous polarization. For example, the plurality of ferroelectric layers FRL1 and FRL2 each may include at least one of hafnium oxide (HfO₂), lead zirconate titanate (PbZrTi (PZT)), and/or the like. In a least one embodiment, the ferroelectric layers FRL1 and FRL2 may include Hafnium oxide (HfO₂) doped with at least one of silicon (Si), lanthanum (La), yttrium (Y), aluminum (Al), zirconium (Zr), gadolinium (Gd), and/or the like. However, the examples are not limited thereto, and the plurality of ferroelectric layers FRL1 and FRL2 each may include other ferroelectric materials.

The plurality of insulating layers AFRL1 and AFRL2 may comprise a material without spontaneous polarization. For example, the plurality of insulating layers AFRL1 and AFRL2 each may include at least one of an antiferroelectric layer having no spontaneous polarization in which permanent dipoles are arranged in different directions and/or a paraelectric layer in which permanent dipoles do not exist. For example, the plurality of insulating layers AFRL1 and AFRL2 each may include at least one of zirconium dioxide (ZrO₂), HfₓZr₁₋ₓO₂ (x<0.5), AgNbO₃, and/or the like, but the examples are not limited thereto.

The auxiliary pattern LF may include a material having E_{g}<4.0 eV. For example, the auxiliary pattern LF may include metal oxide having the energy band gap E_{g} lower than about 4.0 eV. For example, the auxiliary pattern LF may include at least one of zinc oxide (ZnO), tin oxide (SnO₂), indium oxide (In₂O₃), titanium dioxide (TiO₂), tungsten trioxide (WO₃), niobium pentoxide (Nb₂O₅), manganese monoxide (MnO), nickel oxide (NiO), and/or the like.

The plurality of auxiliary patterns LF may be dispersed inside the plurality of ferroelectric layers FRL1 and FRL2, and each may be a thin film having an atypical form. A planar area of each of the plurality of auxiliary patterns LF may be smaller than a planar area of each of the plurality of ferroelectric layers FRL1 and FRL2.

For example, a ratio of the plurality of auxiliary patterns LF in the dielectric layer DIL may be about 3% to about 10%.

According to the capacitor 103, the plurality of auxiliary patterns LF may weaken the ferroelectricity of the plurality of ferroelectric layers FRL1 and FRL2, and accordingly, deterioration in which a polarization state of each of the plurality of ferroelectric layers FRL1 and FRL2 remains in a previous polarization state without being completely restored to a state before a voltage is applied may be reduced (and/or prevented). In addition, the polarization state is maintained without being restored by the ferroelectricity of the plurality of ferroelectric layers FRL1 and FRL2, thereby reducing (or preventing) the leakage current of the dielectric layer DIL that may occur.

In addition, according to the capacitor 103, the dielectric layer DIL includes the plurality of insulating layers AFRL1 and AFRL2 that respectively overlap the plurality of ferroelectric layers FRL1 and FRL2 and do not have spontaneous polarization, and thus, the overall ferroelectricity within the dielectric layer DIL may be reduced, thereby reducing (and/or preventing) deterioration and leakage current of the dielectric layer DIL.

The number of layers of the plurality of ferroelectric layers FRL1 and FRL2 and the number of layers of the plurality of insulating layers AFRL1 and AFRL2 are not limited to the number of layers in the illustrated embodiment.

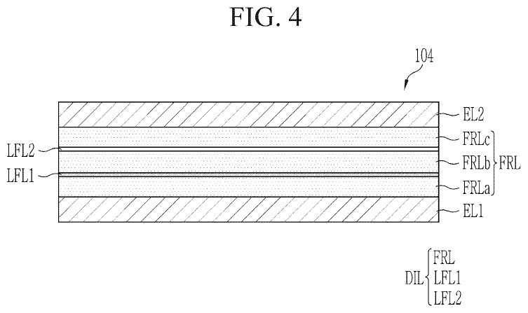

A capacitor 104 according to at least one embodiment is described with reference to FIG. 4. FIG. 4 is a cross-sectional view of a capacitor 104 according to at least one embodiment.

Referring to FIG. 4, detailed descriptions of elements of the capacitor 104 substantially similar to (or the same as) elements of the capacitors 101, 102, and/or 103 may be omitted.

Referring to FIG. 4, the capacitor 104 may include the first electrode EL1 and the second electrode EL2 facing each other and the dielectric layer DIL disposed between the first electrode EL1 and the second electrode EL2.

The first electrode EL1 and the second electrode EL2 each may include a conductive material.

A leakage current of the dielectric layer DIL may be 10⁻⁴ A/cm²≤x≤10⁻⁸ A/cm² (e.g., at 1 V) 10-4 A/cm2≤x≤10-8 A/cm2 (e.g., at 1 V). A thickness of the dielectric layer DIL may be greater than 0 and less than or equal to about 50 Å, but the examples are not limited thereto.

The dielectric layer DIL of the capacitor 104 may include the ferroelectric layer FRL and a plurality of auxiliary layers LFL1 and LFL2 disposed in the ferroelectric layer FRL.

The ferroelectric layer FRL may include a plurality of sub ferroelectric layers FRLa, FRLb, and FRLc disposed between the first and second electrodes EL1 and EL2 facing each other, and the plurality of auxiliary layers LFL1 and LFL2 may be disposed between the plurality of sub ferroelectric layers FRLa, FRLb, and FRLc.

The ferroelectric layers FRLa through FRLc may include a ferroelectric material having spontaneous polarization. In at least one embodiment, the ferroelectric layer FRL may include at least one of hafnium oxide (HfO₂) and/or lead zirconate titanate (PbZrTi (PZT)). For example, the ferroelectric layer FRL may include hafnium oxide (HfO₂) doped with at least one of silicon (Si), lanthanum (La), yttrium (Y), aluminum (Al), zirconium (Zr), gadolinium (Gd), and/or the like. However, the examples are not limited thereto, and the ferroelectric layers FRLa through FRLc may include other ferroelectric materials.

The plurality of auxiliary layers LFL1 and LFL2 each may include a material having E_{g}<4.0 eV. For example, the auxiliary pattern LF may include metal oxide having the energy band gap E_{g} lower than about 4.0 eV. For example, the plurality of auxiliary layers LFL1 and LFL2 each may include at least one of zinc oxide (ZnO), tin oxide (SnO₂), indium oxide (In₂O₃), titanium dioxide (TiO₂), tungsten trioxide (WO₃), niobium pentoxide (Nb₂O₅), manganese monoxide (MnO), nickel oxide (NiO), and/or the like.

The plurality of auxiliary layers LFL1 and LFL2 may be disposed between the plurality of sub ferroelectric layers FRLa, FRLb, and FRLc, and each may be in the form of a thin film layer between the plurality of sub ferroelectric layers FRLa, FRLb, and FRLc. In these cases, the auxiliary layers LFL1 and LFL 2 may also be referred to as auxiliary thin film layers. A thickness of the plurality of auxiliary layers LFL1 and LFL2 may be smaller than a thickness of the plurality of sub ferroelectric layers FRLa, FRLb and FRLc.

For example, a ratio of the plurality of auxiliary layers LFL1 and LFL2 in the dielectric layer DIL may be about 3% to about 10%.

According to the capacitor 104, the plurality of auxiliary layers LFL1 and LFL2 may weaken the ferroelectricity of the ferroelectric layer FRL, and accordingly, deterioration in which a polarization state of the ferroelectric layer FRL remains in a previous polarization state without being completely restored to a state before a voltage is applied may be reduced (and/or prevented). In addition, the polarization state is maintained without being restored by the ferroelectricity of the ferroelectric layer FRL, thereby reducing the leakage current of the dielectric layer DIL that may occur.

The number of layers of the plurality of sub ferroelectric layers FRLa, FRLb and FRLc of the ferroelectric layer FRL and the number of layers of the plurality of auxiliary layers LFL1 and LFL2 are not limited to the number of layers in the illustrated embodiment.

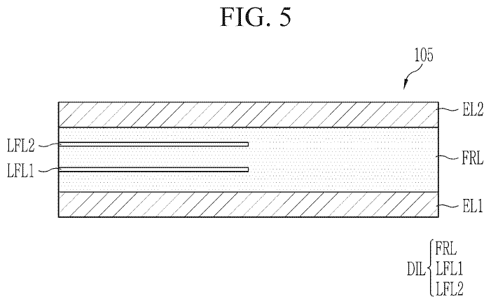

A capacitor 105 according to at least one embodiment is described with reference to FIG. 5. FIG. 5 is a cross-sectional view of a capacitor 105 according to at least one embodiment.

Referring to FIG. 5, detailed descriptions of elements of the capacitor 105 substantially similar to (or the same as) as elements of the capacitors 101, 102, 103, and 104 may be omitted.

Referring to FIG. 5, the capacitor 105 may include the first electrode EL1 and the second electrode EL2 facing each other and the dielectric layer DIL disposed between the first electrode EL1 and the second electrode EL2.

The first electrode EL1 and the second electrode EL2 each may include a conductive material.

A leakage current of the dielectric layer DIL may be 10⁻⁴ A/cm²≤x≤10⁻⁸ A/cm² (e.g., at 1 V). A thickness of the dielectric layer DIL may be greater than 0 and less than or equal to about 50 Å, but the examples are not limited thereto.

The dielectric layer DIL of the capacitor 105 may include the ferroelectric layer FRL and a plurality of auxiliary layers LFL1 and LFL2 disposed in the ferroelectric layer FRL.

The plurality of auxiliary layers LFL1 and LFL2 may be inserted into the ferroelectric layer FRL. The plurality of auxiliary layers LFL1 and LFL2 each may have the form of a thin film layer and may partially overlap the ferroelectric layer FRL. In these cases, the auxiliary layers LFL1 and LFL 2 may also be referred to as auxiliary thin film layers. A planar area of the plurality of auxiliary layers LFL1 and LFL2 may be smaller than a planar area of the ferroelectric layer FRL.

The ferroelectric layer FRL may include a ferroelectric material having spontaneous polarization. In at least one embodiment, the ferroelectric layer FRL may include at least one of hafnium oxide (HfO₂) and/or lead zirconate titanate (PbZrTi (PZT)). For example, the ferroelectric layer FRL may include hafnium oxide (HfO₂) doped with at least one of silicon (Si), lanthanum (La), yttrium (Y), aluminum (Al), zirconium (Zr), gadolinium (Gd), and/or the like. However, the examples are not limited thereto, and the ferroelectric layer FRL may include other ferroelectric materials. In at least one embodiment, the ferroelectric layer FRL may include at least one of hafnium oxide (HfO2) and/or lead zirconate titanate (PbZrTi (PZT)). For example, the ferroelectric layer FRL.

The plurality of auxiliary layers LFL1 and LFL2 each may include a material having E_{g}<4.0 eV. For example, the auxiliary layers LF1 and LFT2 each may include metal oxide having the energy band gap E_{g} lower than about 4.0 eV. For example, the auxiliary pattern LF may include at least one of zinc oxide (ZnO), tin oxide (SnO₂), indium oxide (In₂O₃), titanium dioxide (TiO₂), tungsten trioxide (WO₃), niobium pentoxide (Nb₂O₅), manganese monoxide (MnO), nickel oxide (NiO), and/or the like.

A thickness of the plurality of auxiliary layers LFL1 and LFL2 may be smaller than a thickness of the ferroelectric layer FRL.

For example, a ratio of the plurality of auxiliary layers LFL1 and LFL2 in the dielectric layer DIL may be about 3% to about 10%.

According to the capacitor 105, the plurality of auxiliary layers LFL1 and LFL2 may weaken the ferroelectricity of the ferroelectric layer FRL, and accordingly, deterioration in which a polarization state of the ferroelectric layer FRL remains in a previous polarization state without being completely restored to a state before a voltage is applied may be reduced (or prevented). In addition, the polarization state is maintained without being restored by the ferroelectricity of the ferroelectric layer FRL, thereby reducing the leakage current of the dielectric layer DIL that may occur.

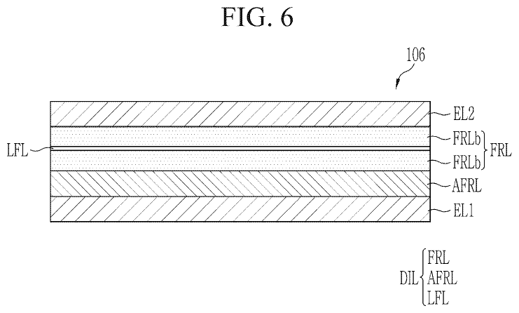

A capacitor 106 according to at least one embodiment is described with reference to FIG. 6. FIG. 6 is a cross-sectional view of a capacitor 106 according to at least one embodiment.

Referring to FIG. 6, detailed descriptions of elements of the capacitor 102 substantially similar to (or the same as) elements of the capacitors 101, 102, 103, 104, and 105 may be omitted.

Referring to FIG. 6, the capacitor 106 may include the first electrode EL1 and the second electrode EL2 facing each other and the dielectric layer DIL disposed between the first electrode EL1 and the second electrode EL2.

The first electrode EL1 and the second electrode EL2 each may include a conductive material.

A leakage current of the dielectric layer DIL may be 10⁻⁴ A/cm²≤x≤10⁻⁸ A/cm² (e.g., at 1 V). A thickness of the dielectric layer DIL may be greater than 0 and less than or equal to about 50 Å, but the examples are not limited thereto.

The dielectric layer DIL of the capacitor 106 may include the ferroelectric layer FRL, the auxiliary layer LFL disposed in the ferroelectric layer FRL, and the insulating layer AFRL.

The ferroelectric layer FRL and the insulating layer AFRL may overlap each other between the first electrode EL1 and the second electrode EL2 facing each other.

The ferroelectric layer FRL may include the plurality of sub ferroelectric layers FRLa and FRLb, and the auxiliary layer LFL may be disposed between the plurality of sub ferroelectric layers FRLa and FRLb.

The ferroelectric layer FRL may include a ferroelectric material having spontaneous polarization. In at least one embodiment, the ferroelectric layer FRL may include at least one of hafnium oxide (HfO₂) and/or lead zirconate titanate (PbZrTi (PZT)). For example, the ferroelectric layer FRL may include hafnium oxide (HfO₂) doped with at least one of silicon (Si), lanthanum (La), yttrium (Y), aluminum (Al), zirconium (Zr), gadolinium (Gd), and/or the like. However, the examples are not limited thereto, and the ferroelectric layer FRL may include other ferroelectric materials.

The auxiliary pattern LF may include a material having E_{g}<4.0 eV. For example, the auxiliary pattern LF may include metal oxide having the energy band gap E_{g} lower than about 4.0 eV. For example, the auxiliary pattern LF may include at least one of zinc oxide (ZnO), tin oxide (SnO₂), indium oxide (In₂O₃), titanium dioxide (TiO₂), tungsten trioxide (WO₃), niobium pentoxide (Nb₂O₅), manganese monoxide (MnO), nickel oxide (NiO), and/or the like.

The auxiliary layer LFL may be in the form of a thin film layer between the plurality of sub ferroelectric layers FRLa and FRLb. In these cases, the auxiliary layer LFL may also be referred to as an auxiliary thin film layer. A thickness of the auxiliary layer LFL may be smaller than a thickness of the plurality of sub ferroelectric layers FRLa and FRLb.

For example, a ratio of the auxiliary layer LFL in the dielectric layer DIL may be about 3% to about 10%.

The insulating layer AFRL may comprise a material without spontaneous polarization. For example, the insulating layer AFRL may include at least one of an antiferroelectric layer having no spontaneous polarization in which permanent dipoles are arranged in different directions and/or a paraelectric layer in which permanent dipoles do not exist. For example, the insulating layer AFRL may include at least one of zirconium dioxide (ZrO₂), HfₓZr₁₋ₓO₂ (x<0.5), or AgNbO₃, but the examples are not limited thereto.

According to the capacitor 106, the auxiliary layer LFL may weaken the ferroelectricity of the ferroelectric layer FRL, and accordingly, deterioration in which a polarization state of the ferroelectric layer FRL remains in a previous polarization state without being completely restored to a state before a voltage is applied may be reduced (and/or prevented). In addition, the polarization state is maintained without being restored by the ferroelectricity of the ferroelectric layer FRL, thereby reducing the leakage current of the dielectric layer DIL that may occur.

In addition, according to the capacitor 106, the dielectric layer DIL further includes the insulating layer AFRL that overlaps the ferroelectric layer FRL and does not have spontaneous polarization, and thus, overall ferroelectricity within the dielectric layer DIL may be reduced, thereby reducing (and/or preventing) deterioration and leakage current of the dielectric layer DIL.

The number of layers of the plurality of sub ferroelectric layers FRLa and FRLb of the ferroelectric layer FRL and the number of layers of the auxiliary layer LFL are not limited to the number of layers in the illustrated embodiment.

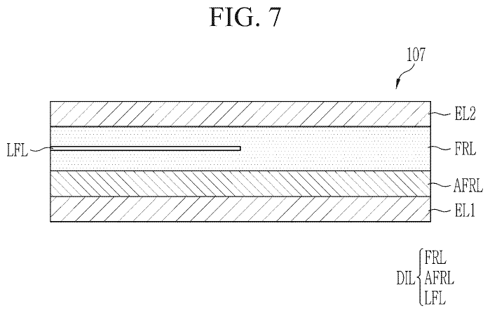

A capacitor 107 according to at least one embodiment is described with reference to FIG. 7. FIG. 7 is a cross-sectional view of a capacitor 107 according to at least one embodiment.

Referring to FIG. 7, detailed descriptions of elements of the capacitor 107 substantially similar to (or the same as) elements of the capacitors 101, 102, 103, 104, 105, and 106 may be omitted.

Referring to FIG. 7, the capacitor 107 may include the first electrode EL1 and the second electrode EL2 facing each other and the dielectric layer DIL disposed between the first electrode EL1 and the second electrode EL2.

The first electrode EL1 and the second electrode EL2 each may include a conductive material.

A leakage current of the dielectric layer DIL may be 10⁻⁴ A/cm²≤x≤10⁻⁸ A/cm² (e.g., at 1 V). A thickness of the dielectric layer DIL may be greater than 0 and less than or equal to about 50 Å, but the examples are not limited thereto.

The dielectric layer DIL of the capacitor 107 may include the ferroelectric layer FRL, the auxiliary layer LFL disposed in the ferroelectric layer FRL, and the insulating layer AFRL.

The ferroelectric layer FRL and the insulating layer AFRL may overlap each other between the first electrode EL1 and the second electrode EL2 facing each other. For example, the insulating layer AFRL may be disposed between the ferroelectric layer FRL and at least one of the first electrode EL1 and the second electrode EL2.

The auxiliary layer LFL may be inserted into a part of the ferroelectric layer FRL. The auxiliary layer LFL may have the form of a thin film layer and may partially overlap the ferroelectric layer FRL. In these cases, the auxiliary layer LFL may also be referred to as an auxiliary thin film layer. A planar area of the auxiliary layer LFL may be smaller than a planar area of the ferroelectric layer FRL. A thickness of the auxiliary layer LFL may be smaller than a thickness of the ferroelectric layer FRL.

The ferroelectric layer FRL may include a ferroelectric material having spontaneous polarization. In at least one embodiment, the ferroelectric layer FRL may include at least one of hafnium oxide (HfO₂) and/or lead zirconate titanate (PbZrTi (PZT)). For example, the ferroelectric layer FRL may include hafnium oxide (HfO₂) doped with at least one of silicon (Si), lanthanum (La), yttrium (Y), aluminum (Al), zirconium (Zr), gadolinium (Gd), and/or the like. However, the examples are not limited thereto, and the ferroelectric layer FRL may include other ferroelectric materials.

The auxiliary layer LFL may include a material having E_{g}<4.0 eV. For example, the auxiliary layer LFL may include metal oxide having the energy band gap Eg lower than about 4.0 eV. For example, the auxiliary layer LFL may include at least one of zinc oxide (ZnO), tin oxide (SnO2), indium oxide (In2O3), titanium dioxide (TiO2), tungsten trioxide (WO3), niobium pentoxide (Nb2O5), manganese monoxide (MnO), nickel oxide (NiO), and/or the like.

A ratio of the auxiliary layer LFL in the dielectric layer DIL may be about 3% to about 10%.

The insulating layer AFRL may include a material without spontaneous polarization. For example, the insulating layer AFRL may include at least one of an antiferroelectric layer having no spontaneous polarization in which permanent dipoles are arranged in different directions and/or a paraelectric layer in which permanent dipoles do not exist. For example, the insulating layer AFRL may include at least one of zirconium dioxide (ZrO₂), HfₓZr₁₋ₓO₂ (x<0.5), or AgNbO₃, but the examples are not limited thereto.

According to the capacitor 107, the auxiliary layer LFL may weaken the ferroelectricity of the ferroelectric layer FRL, and accordingly, deterioration in which a polarization state of the ferroelectric layer FRL remains in a previous polarization state without being completely restored to a state before a voltage is applied may be reduced (or prevented).

In addition, the polarization state is maintained without being restored by the ferroelectricity of the ferroelectric layer FRL, thereby reducing the leakage current of the dielectric layer DIL that may occur.

In addition, according to the capacitor 107, the dielectric layer DIL further includes the insulating layer AFRL that overlaps the ferroelectric layer FRL and does not have spontaneous polarization, and thus, overall ferroelectricity within the dielectric layer DIL may be reduced, thereby reducing (or preventing) deterioration and leakage current of the dielectric layer DIL.

The number of layers of the auxiliary layer LFL is not limited to the number of layers in the illustrated embodiment and.

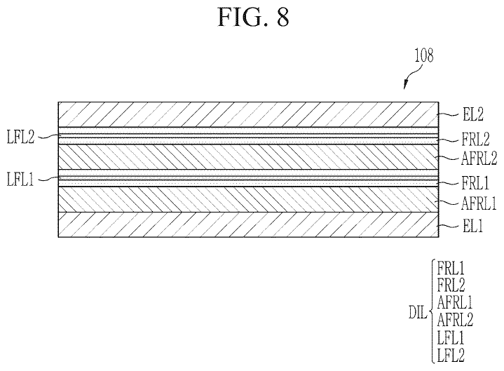

A capacitor 108 according to at least one embodiment is described with reference to FIG. 8. FIG. 8 is a cross-sectional view of a capacitor 108 according to at least one embodiment.

Referring to FIG. 8, detailed descriptions of elements of the capacitor 108 substantially similar to (or the same as) the capacitors 101, 102, 103, 104, 105, 106, and 107 may be omitted.

Referring to FIG. 8, the capacitor 108 may include the first electrode EL1 and the second electrode EL2 facing each other and the dielectric layer DIL disposed between the first electrode EL1 and the second electrode EL2.

The first electrode EL1 and the second electrode EL2 each may include a conductive material.

A leakage current of the dielectric layer DIL may be 10⁻⁴ A/cm²≤x≤10⁻⁸ A/cm² (e.g., at 1 V). A thickness of the dielectric layer DIL may be greater than 0 and less than or equal to about 50 Å, but the examples are not limited thereto.

The dielectric layer DIL of the capacitor 108 may include the plurality of ferroelectric layers FRL1 and FRL2, the plurality of insulating layers AFRL1 and AFRL2, and the plurality of auxiliary layers LFL1 and LFL2 respectively disposed in the ferroelectric layers FRL1 and FRL2.

The plurality of ferroelectric layers FRL1 and FRL2 and the plurality of insulating layers AFRL1 and AFRL2 may overlap each other and be alternately disposed between the first and second electrodes EL1 and EL2 facing each other, but the examples are not limited thereto.

The plurality of ferroelectric layers FRL1 and FRL2 each may include a ferroelectric material having spontaneous polarization. In at least one embodiment, the plurality of ferroelectric layers FRL1 and FRL2 each may include at least one of hafnium oxide (HfO2) and/or lead zirconate titanate (PbZrTi (PZT)). For example, the ferroelectric layers FRL1 and FRL2 may include hafnium oxide (HfO2) doped with at least one of silicon (Si), lanthanum (La), yttrium (Y), aluminum (Al), zirconium (Zr), gadolinium (Gd), and/or the like. However, the examples are not limited thereto, and the plurality of ferroelectric layers FRL1 and FRL2 each may include other ferroelectric materials.

The plurality of insulating layers AFRL1 and AFRL2 may comprise a material without spontaneous polarization. For example, the plurality of insulating layers AFRL1 and AFRL2 each may include at least one of an antiferroelectric layer having no spontaneous polarization in which permanent dipoles are arranged in different directions and/or a paraelectric layer in which permanent dipoles do not exist. For example, the plurality of insulating layers AFRL1 and AFRL2 each may include at least one of zirconium dioxide (ZrO₂), HfₓZr₁₋ₓO₂ (x<0.5), AgNbO₃, and/or the like, but the examples are not limited thereto.

The auxiliary pattern LF may include a material having E_{g}<4.0 eV. For example, the plurality of auxiliary layers LFL1 and LFL2 each may include metal oxide having the energy band gap Eg lower than about 4.0 eV. For example, the plurality of auxiliary layers LFL1 and LFL2 each may include at least one of zinc oxide (ZnO), tin oxide (SnO₂), indium oxide (In₂O₃), titanium dioxide (TiO₂), tungsten trioxide (WO₃), niobium pentoxide (Nb₂O₅), manganese monoxide (MnO), nickel oxide (NiO), and/or the like.

The plurality of auxiliary layers LFL1 and LFL2 may be respectively disposed inside the plurality of ferroelectric layers FRL1 and FRL2, and each may have the form of a thin film layer. In these cases, the auxiliary layers LFL1 and LFL 2 may also be referred to as auxiliary thin film layers. A thickness of the plurality of auxiliary layers LFL1 and LFL2 may be smaller than a thickness of the plurality of ferroelectric layers FRL1 and FRL2. The plurality of ferroelectric layers FRL1 and FRL2 may be respectively disposed above and below the plurality of auxiliary layers LFL1 and LFL2.

For example, a ratio of the plurality of auxiliary layers LFL1 and LFL2 in the dielectric layer DIL may be about 3% to about 10%.

According to the capacitor 108, the plurality of auxiliary layers LFL1 and LFL2 may respectively weaken the ferroelectricity of the plurality of ferroelectric layers FRL1 and FRL2, and accordingly, deterioration in which a polarization state of each of the plurality of ferroelectric layers FRL1 and FRL2 remains in a previous polarization state without being completely restored to a state before a voltage is applied may be reduced (and/or prevented). In addition, the polarization state is maintained without being restored by the ferroelectricity of the plurality of ferroelectric layers FRL1 and FRL2, thereby reducing the leakage current of the dielectric layer DIL that may occur. In addition, according to the capacitor 108, the dielectric layer DIL includes the plurality of insulating layers AFRL1 and AFRL2 that respectively overlap the plurality of ferroelectric layers FRL1 and FRL2 and do not have spontaneous polarization, and thus, overall ferroelectricity within the dielectric layer DIL may be reduced, thereby reducing (and/or preventing) deterioration and leakage current of the dielectric layer DIL.

The number of layers of the plurality of ferroelectric layers FRL1 and FRL2, the number of layers of the plurality of insulating layers AFRL1 and AFRL2, and the number of layers of the plurality of auxiliary layers LFL1 and LFL2 are not limited to the number of layers in the illustrated embodiment.

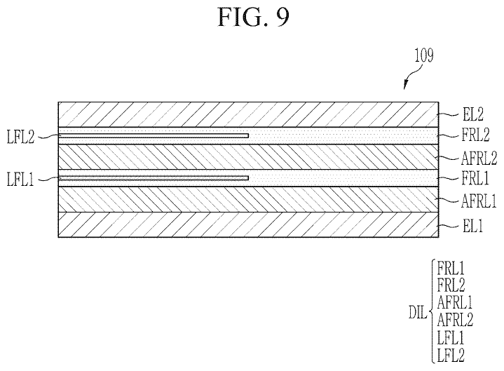

A capacitor 109 according to at least one embodiment is described with reference to FIG. 9. FIG. 9 is a cross-sectional view of a capacitor according to at least one embodiment.

Referring to FIG. 9, detailed descriptions of elements of the capacitor 109 substantially similar to (or the same as) elements of the capacitors 101, 102, 103, 104, 105, 106, 107, and 108 may be omitted.

Referring to FIG. 9, the capacitor 109 may include the first electrode EL1 and the second electrode EL2 facing each other and the dielectric layer DIL disposed between the first electrode EL1 and the second electrode EL2.

The first electrode EL1 and the second electrode EL2 each may include a conductive material.

A leakage current of the dielectric layer DIL may be 10⁻⁴ A/cm²≤x≤10⁻⁸ A/cm² (e.g., at 1 V). A thickness of the dielectric layer DIL may be greater than 0 and less than or equal to about 50 Å, but the examples are not limited thereto.

The dielectric layer DIL of the capacitor 109 may include the plurality of ferroelectric layers FRL1 and FRL2, the plurality of insulating layers AFRL1 and AFRL2, and the plurality of auxiliary layers LFL1 and LFL2 respectively disposed in the ferroelectric layers FRL1 and FRL2.

The plurality of ferroelectric layers FRL1 and FRL2 and the plurality of insulating layers AFRL1 and AFRL2 may overlap each other and be alternately disposed between the first and second electrodes EL1 and EL2 facing each other, but the examples are not limited thereto.

The plurality of ferroelectric layers FRL1 and FRL2 each may include a ferroelectric material having spontaneous polarization. In at least one embodiment, the plurality of ferroelectric layers FRL1 and FRL2 each may include at least one of hafnium oxide (HfO₂) and/or lead zirconate titanate (PbZrTi (PZT)). For example, the ferroelectric layers FRL1 and FRL2 may include hafnium oxide (HfO₂) doped with at least one of silicon (Si), lanthanum (La), yttrium (Y), aluminum (Al), zirconium (Zr), gadolinium (Gd), and/or the like. However, the examples are not limited thereto, and the plurality of ferroelectric layers FRL1 and FRL2 each may include other ferroelectric materials.

The plurality of insulating layers AFRL1 and AFRL2 may include a material without spontaneous polarization. In at least one embodiment, the plurality of insulating layers AFRL1 and AFRL2 each may include at least one of an antiferroelectric layer having no spontaneous polarization in which permanent dipoles are arranged in different directions and/or a paraelectric layer in which permanent dipoles do not exist. For example, the plurality of insulating layers AFRL1 and AFRL2 each may include at least one of zirconium dioxide (ZrO2), HfxZr1-xO2 (x<0.5), AgNbO3, and/or the like, but the examples are not limited thereto.

The plurality of auxiliary layers LFL1 and LFL2 each may include a material having E_{g}<4.0 eV. For example, the auxiliary pattern LF may include metal oxide having the energy band gap E_{g} lower than about 4.0 eV. For example, the plurality of auxiliary layers LFL1 and LFL2 each may include at least one of zinc oxide (ZnO), tin oxide (SnO₂), indium oxide (In₂O₃), titanium dioxide (TiO₂), tungsten trioxide (WO₃), niobium pentoxide (Nb₂O₅), manganese monoxide (MnO), nickel oxide (NiO), and/or the like.

The plurality of auxiliary layers LFL1 and LFL2 may be respectively disposed inside a part of the plurality of ferroelectric layers FRL1 and FRL2, and each may have the form of a thin film layer. In these cases, the auxiliary layers LFL1 and LFL 2 may also be referred to as auxiliary thin film layers. The plurality of auxiliary layers LFL1 and LFL2 may respectively partially overlap a part of the plurality of ferroelectric layers FRL1 and FRL2. For example, a planar area of the plurality of auxiliary layers LFL1 and LFL2 may be smaller than a planar area of the plurality of ferroelectric layers FRL1 and FRL2. A thickness of the plurality of auxiliary layers LFL1 and LFL2 may be smaller than a thickness of the plurality of ferroelectric layers FRL1 and FRL2. The plurality of ferroelectric layers FRL1 and FRL2 may be respectively disposed above and below the plurality of auxiliary layers LFL1 and LFL2.

For example, a ratio of the plurality of auxiliary layers LFL1 and LFL2 in the dielectric layer DIL may be about 3% to about 10%.

According to the capacitor 109, the plurality of auxiliary layers LFL1 and LFL2 may respectively weaken the ferroelectricity of the plurality of ferroelectric layers FRL1 and FRL2, and accordingly, deterioration in which a polarization state of each of the plurality of ferroelectric layers FRL1 and FRL2 remains in a previous polarization state without being completely restored to a state before a voltage is applied may be reduced (and/or prevented). In addition, the polarization state is maintained without being restored by the ferroelectricity of the plurality of ferroelectric layers FRL1 and FRL2, thereby reducing the leakage current of the dielectric layer DIL that may occur.

In addition, according to the capacitor 109, the dielectric layer DIL includes the plurality of insulating layers AFRL1 and AFRL2 that respectively overlap the plurality of ferroelectric layers FRL1 and FRL2 and do not have spontaneous polarization, and thus, overall ferroelectricity within the dielectric layer DIL may be reduced, thereby reducing (and/or preventing) deterioration and leakage current of the dielectric layer DIL.

The number of layers of the plurality of ferroelectric layers FRL1 and FRL2, the number of layers of the plurality of insulating layers AFRL1 and AFRL2, and the number of layers of the plurality of auxiliary layers LFL1 and LFL2 are not limited to the number of layers in the illustrated embodiment.

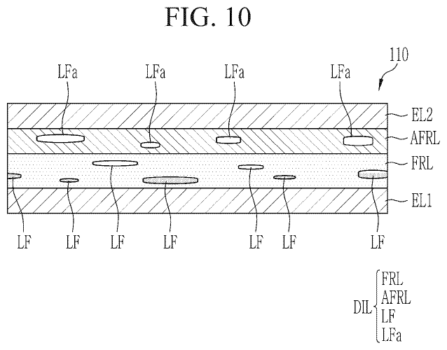

A capacitor 110 according to at least one embodiment is described with reference to FIG. 10. FIG. 10 is a cross-sectional view of a capacitor 110 according to at least one embodiment.

Referring to FIG. 10, detailed descriptions of elements of the capacitor 105 substantially similar to (or the same as) as elements of the capacitor 110 similar to (and/or the same as) the capacitors 101, 102, 103, 104, 105, 106, 107, 108, and 109 may be omitted.

Referring to FIG. 10, the capacitor 110 may include the first electrode EL1 and the second electrode EL2 facing each other and the dielectric layer DIL disposed between the first electrode EL1 and the second electrode EL2.

The first electrode EL1 and the second electrode EL2 each may include a conductive material.

A leakage current of the dielectric layer DIL may be 10⁻⁴ A/cm²≤x≤10⁻⁸ A/cm² (e.g., at 1 V). A thickness of the dielectric layer DIL may be greater than 0 and less than or equal to about 50 Å, but the examples are not limited thereto.

The dielectric layer DIL of the capacitor 110 may include the ferroelectric layer FRL, the plurality of auxiliary patterns LF dispersed in the ferroelectric layer FRL, the insulating layer AFRL, and a plurality of auxiliary patterns LFa dispersed in the insulating layer AFRL.

The ferroelectric layer FRL and the insulating layer AFRL may overlap each other between the first electrode EL1 and the second electrode EL2 facing each other. For example, the insulating layer AFRL may be disposed between the ferroelectric layer FRL and at least one of the first electrode EL1 and the second electrode EL2.

The ferroelectric layer FRL may include a ferroelectric material having spontaneous polarization. In at least one embodiment, the ferroelectric layer FRL may include at least one of hafnium oxide (HfO2) and/or lead zirconate titanate (PbZrTi (PZT)). For example, the ferroelectric layer FRL may include hafnium oxide (HfO2) doped with at least one of silicon (Si), lanthanum (La), yttrium (Y), aluminum (Al), zirconium (Zr), gadolinium (Gd), and/or the like However, the examples are not limited thereto, and the ferroelectric layer FRL may include other ferroelectric materials.

The insulating layer AFRL may include a material without spontaneous polarization. For example, the insulating layer AFRL may include at least one of an antiferroelectric layer having no spontaneous polarization in which permanent dipoles are arranged in different directions and/or a paraelectric layer in which permanent dipoles do not exist. For example, the insulating layer AFRL may include at least one of zirconium dioxide (ZrO₂), HfₓZr₁₋ₓO₂ (x<0.5), AgNbO₃, and/or the like, but the examples are not limited thereto.

The auxiliary patterns LF and LFa each may include a material having E_{g}<4.0 eV. For example, the auxiliary pattern LF may include metal oxide having the energy band gap E_{g} lower than about 4.0 eV. For example, the auxiliary patterns LF and LFa each may include at least one of zinc oxide (ZnO), tin oxide (SnO2), indium oxide (In₂O₃), titanium dioxide (TiO₂), tungsten trioxide (WO₃), niobium pentoxide (Nb₂O), manganese monoxide (MnO), nickel oxide (NiO), and/or the like.

The plurality of auxiliary patterns LF and LFa may be respectively dispersed inside the ferroelectric layer FRL and the insulating layer AFRL, and each may be a thin film having an atypical form. A planar area of each of the plurality of auxiliary patterns LF and LFa may be smaller than a planar area of the ferroelectric layer FRL or a planar area of the insulating layer AFRL.

For example, a ratio of the plurality of auxiliary patterns LF and LFa in the dielectric layer DIL may be about 3% to about 10%.

According to the capacitor 110, the plurality of auxiliary patterns LF and LFa may weaken the ferroelectricity of the dielectric layer DIL, and accordingly, deterioration in which a polarization state of the ferroelectric layer FRL included in the dielectric layer DIL remains in a previous polarization state without being completely restored to a state before a voltage is applied may be reduced (and/or prevented). In addition, the polarization state is maintained without being restored by the ferroelectricity of the ferroelectric layer FRL included in the dielectric layer DIL, thereby reducing the leakage current of the dielectric layer DIL that may occur.

In addition, according to the capacitor 110, the dielectric layer DIL further includes the insulating layer AFRL that overlaps the ferroelectric layer FRL and does not have spontaneous polarization, and thus, overall ferroelectricity within the dielectric layer DIL may be reduced, thereby reducing (or preventing) deterioration and leakage current of the dielectric layer DIL.

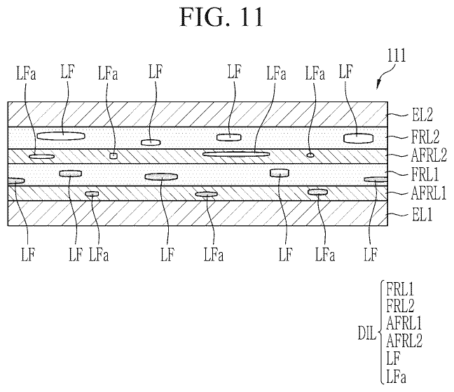

A capacitor 111 according to at least one embodiment is described with reference to FIG. 11. FIG. 11 is a cross-sectional view of a capacitor 111 according to at least one embodiment.

Referring to FIG. 11, detailed descriptions of elements of the capacitor 111 substantially similar to (or the same as) elements of capacitors 101, 102, 103, 104, 105, 106, 107, 108, 109, and 110 may be omitted.

Referring to FIG. 11, the capacitor 111 may include the first electrode EL1 and the second electrode EL2 facing each other and the dielectric layer DIL disposed between the first electrode EL1 and the second electrode EL2.

The first electrode EL1 and the second electrode EL2 each may include a conductive material.

A leakage current of the dielectric layer DIL may be 10⁻⁴ A/cm²≤x≤10⁻⁸ A/cm² (e.g., at 1 V). A thickness of the dielectric layer DIL may be greater than 0 and less than or equal to about 50 Å, but the examples are not limited thereto.

The dielectric layer DIL of the capacitor 111 may include the plurality of ferroelectric layers FRL1 and FRL2, the plurality of insulating layers AFRL1 and AFRL2, the plurality of auxiliary patterns LF dispersed in the ferroelectric layers FRL1 and FRL2, and the plurality of auxiliary patterns LFa dispersed in the plurality of insulating layers AFRL1 and AFRL2.

The plurality of ferroelectric layers FRL1 and FRL2 and the plurality of insulating layers AFRL1 and AFRL2 may overlap each other and be alternately disposed between the first and second electrodes EL1 and EL2 facing each other, but the examples are not limited thereto.

The plurality of ferroelectric layers FRL1 and FRL2 each may include a ferroelectric material having spontaneous polarization. In at least one embodiment, the plurality of ferroelectric layers FRL1 and FRL2 each may include at least one of hafnium oxide (HfO₂) and/or lead zirconate titanate (PbZrTi (PZT)). For example, the ferroelectric layers FRL1 and FRL2 may include hafnium oxide (HfO2) doped with at least one of silicon (Si), lanthanum (La), yttrium (Y), aluminum (Al), zirconium (Zr), and/or the like gadolinium (Gd). However, the examples are not limited thereto, and the plurality of ferroelectric layers FRL1 and FRL2 each may include other ferroelectric materials.

The plurality of insulating layers AFRL1 and AFRL2 may include a material without spontaneous polarization. For example, the plurality of insulating layers AFRL1 and AFRL2 each may include at least one of an antiferroelectric layer having no spontaneous polarization in which permanent dipoles are arranged in different directions and/or a paraelectric layer in which permanent dipoles do not exist. For example, the plurality of insulating layers AFRL1 and AFRL2 each may include at least one of zirconium dioxide (ZrO2), HfxZr1-xO2 (x<0.5), AgNbO3, and/or the like, but the examples are not limited thereto.

The plurality of auxiliary patterns LF and LFa include a material having E_{g}<4.0 eV. For example, the auxiliary pattern LF may include metal oxide having the energy band gap E_{g} lower than about 4.0 eV. For example, the plurality of auxiliary patterns LF and Lfa each may include at least one of zinc oxide (ZnO), tin oxide (SnO₂), indium oxide (In₂O₃), titanium dioxide (TiO₂), tungsten trioxide (WO₃), niobium pentoxide (Nb2O5), manganese monoxide (MnO), nickel oxide (NiO), and/or the like.

The plurality of auxiliary patterns LF and LFa may be respectively dispersed inside the plurality of ferroelectric layers FRL1 and FRL2 and the plurality of insulating layers AFRL1 and AFRL2, and each may be, e.g., a thin film having an atypical form. A planar area of each of the plurality of auxiliary patterns LF and LFa may be smaller than a planar area of each of the plurality of ferroelectric layers FRL1 and FRL2 and a planar area of each of the plurality of insulating layers AFRL1 and AFRL2.

For example, a ratio of the plurality of auxiliary patterns LF and LFa in the dielectric layer DIL may be about 3% to about 10%.

According to the capacitor 111, the plurality of auxiliary patterns LF and LFa may weaken the ferroelectricity of the dielectric layer DIL, and accordingly, deterioration in which a polarization state of the dielectric layer DIL remains in a previous polarization state without being completely restored to a state before a voltage is applied may be reduced (and/or prevented). In addition, the polarization state is maintained without being restored by the ferroelectricity of the dielectric layer DIL, thereby reducing (and/or preventing) the leakage current of the dielectric layer DIL that may occur.

In addition, according to the capacitor 111, the dielectric layer DIL includes the plurality of insulating layers AFRL1 and AFRL2 that respectively overlap the plurality of ferroelectric layers FRL1 and FRL2 and do not have spontaneous polarization, and thus, overall ferroelectricity within the dielectric layer DIL may be reduced, thereby reducing (and/or preventing) deterioration and leakage current of the dielectric layer DIL.

The number of layers of the plurality of ferroelectric layers FRL1 and FRL2 and the number of layers of the plurality of insulating layers AFRL1 and AFRL2 are not limited to the number of layers in the illustrated embodiment.

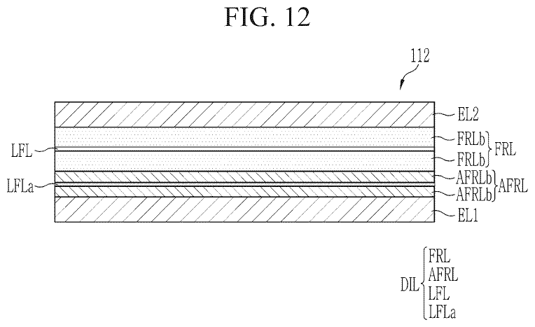

A capacitor 112 according to at least one embodiment is described with reference to FIG. 12. FIG. 12 is a cross-sectional view of a capacitor 112 according to at least one embodiment.

Referring to FIG. 12, detailed descriptions of the capacitor 112 substantially similar to (or the same as) elements of the capacitors 101, 102, 103, 104, 105, 106, 107, 108, 109, 110, and 111 may be omitted.

Referring to FIG. 12, the capacitor 112 may include the first electrode EL1 and the second electrode EL2 facing each other and the dielectric layer DIL disposed between the first electrode EL1 and the second electrode EL2.

The first electrode EL1 and the second electrode EL2 each may include a conductive material.

A leakage current of the dielectric layer DIL may be 10⁻⁴ A/cm²≤x≤10⁻⁸ A/cm² (e.g., at 1 V). A thickness of the dielectric layer DIL may be less than or equal to about 50 Å, but the examples are not limited thereto.

The dielectric layer DIL of the capacitor 112 may include the ferroelectric layer FRL, the auxiliary layer LFL disposed in the ferroelectric layer FRL, the insulating layer AFRL, and an auxiliary layer LFLa disposed in the insulating layer AFRL.

The ferroelectric layer FRL and the insulating layer AFRL may overlap each other between the first electrode EL1 and the second electrode EL2 facing each other.

The ferroelectric layer FRL may include a plurality of sub ferroelectric layers FRLa and FRLb, and the auxiliary layer LFL may be disposed between the plurality of sub ferroelectric layers FRLa and FRLb. The insulating layer AFRL may include a plurality of sub insulating layers AFRLa and AFRLb, and the auxiliary layer LFLa may be disposed between the plurality of sub insulating layers AFRLa and AFRLb.

The ferroelectric layer FRL may include a ferroelectric material having spontaneous polarization. In at least one embodiment, the ferroelectric layer FRL may include at least one of hafnium oxide (HfO2) and/or lead zirconate titanate (PbZrTi (PZT)). For example, the ferroelectric layer FRL may include hafnium oxide (HfO2) doped with at least one of silicon (Si), lanthanum (La), yttrium (Y), aluminum (Al), zirconium (Zr), gadolinium (Gd) and/or the like. However, the examples are not limited thereto, and the ferroelectric layer FRL may include other ferroelectric materials.

The insulating layer AFRL may include a material without spontaneous polarization. For example, the insulating layer AFRL may include at least one of an antiferroelectric layer having no spontaneous polarization in which permanent dipoles are arranged in different directions and/or a paraelectric layer in which permanent dipoles do not exist. For example, the insulating layer AFRL may include at least one of zirconium dioxide (ZrO2), HfₓZr₁₋ₓO₂ (x<0.5), AgNbO₃, and/or the like, but the examples are not limited thereto.

The auxiliary layers LFL and LFLa each may include a material having E_{g}<4.0 eV. For example, the auxiliary layers LFL and LFLa may include metal oxide having the energy band gap E_{g} lower than about 4.0 eV. For example, the auxiliary layers LFL and LFLa each may include at least one of zinc oxide (ZnO), tin oxide (SnO2), indium oxide (In2O3), titanium dioxide (TiO2), tungsten trioxide (WO3), niobium pentoxide (Nb2O5), manganese monoxide (MnO), nickel oxide (NiO), and/or the like.

The auxiliary layers LFL and LFLa each may be in the form of a thin film layer such as the plurality of sub ferroelectric layers FRLa and FRLb and the plurality of sub insulating layers AFRLa and AFRLb. A thickness of the auxiliary layer LFL may be smaller than a thickness of the plurality of sub ferroelectric layers FRLa and FRLb and a thickness of the plurality of sub insulating layers AFRLa and AFRLb.

For example, a ratio of the auxiliary layers LFL and LFLa in the dielectric layer DIL may be about 3% to about 10%.

According to the capacitor 112, the auxiliary layers LFL and LFLa may weaken the ferroelectricity of the dielectric layer DIL, and accordingly, deterioration in which a polarization state of the dielectric layer DIL remains in a previous polarization state without being completely restored to a state before a voltage is applied may be reduced (and/or prevented). In addition, the polarization state is maintained without being restored by the ferroelectricity of the dielectric layer DIL, thereby reducing the leakage current of the dielectric layer DIL that may occur.

In addition, according to the capacitor 112, the dielectric layer DIL further includes the insulating layer AFRL that overlaps the ferroelectric layer FRL and does not have spontaneous polarization, and thus, overall ferroelectricity within the dielectric layer DIL may be reduced, thereby reducing (and/or preventing) deterioration and leakage current of the dielectric layer DIL.

The number of layers of the plurality of sub ferroelectric layers FRLa and FRLb of the ferroelectric layer FRL, the number of layers of the plurality of sub insulating layers AFRLa and AFRLb, and the number of layers of the auxiliary layers LFL and LFLa are not limited to the number of layers in the illustrated embodiment.

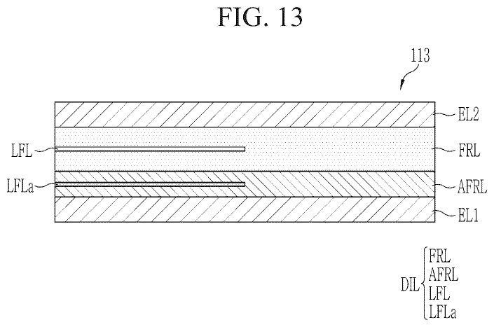

A capacitor 113 according to at least one embodiment is described with reference to FIG. 13. FIG. 13 is a cross-sectional view of a capacitor 113 according to at least one embodiment.

Referring to FIG. 13, detailed descriptions of elements of the capacitor 113 substantially similar to (or the same as) the capacitors 101, 102, 103, 104, 105, 106, 107, 108, 109, 110, 111, and 112 may be omitted.

Referring to FIG. 13, the capacitor 113 may include the first electrode EL1 and the second electrode EL2 facing each other and the dielectric layer DIL disposed between the first electrode EL1 and the second electrode EL2.

The first electrode EL1 and the second electrode EL2 each may include a conductive material.

A leakage current of the dielectric layer DIL may be 10⁻⁴ A/cm²≤x≤10⁻⁸ A/cm² (e.g., at 1 V). A thickness of the dielectric layer DIL may be less than or equal to about 50 Å, but the examples are not limited thereto.

The dielectric layer DIL of the capacitor 113 may include the ferroelectric layer FRL, the auxiliary layer LFL disposed in the ferroelectric layer FRL, the insulating layer AFRL, and the auxiliary layer LFLa disposed in the insulating layer AFRL.

The ferroelectric layer FRL and the insulating layer AFRL may overlap each other between the first electrode EL1 and the second electrode EL2 facing each other.

The auxiliary layer LFL may be inserted into a part of the ferroelectric layer FRL, and the auxiliary layer LFLa may be inserted into a part of the insulating layer AFRL. The auxiliary layers LFL and LFLa each may have the form of a thin layer and may respectively partially overlap each of the ferroelectric layer FRL and the insulating layer AFRL. A planar area of the auxiliary layers LFL and LFLa may be smaller than a planar area of the ferroelectric layer FRL and a planar area of the insulating layer AFRL. A thickness of the auxiliary layers LFL and LFLa may be smaller than a thickness of the ferroelectric layer FRL and a thickness of the insulating layer AFRL.

The ferroelectric layer FRL may include a ferroelectric material having spontaneous polarization. In at least one embodiment, the ferroelectric layer FRL may include at least one of hafnium oxide (HfO2) and/or lead zirconate titanate (PbZrTi (PZT)). For example, the ferroelectric layer FRL may include hafnium oxide (HfO2) doped with at least one of silicon (Si), lanthanum (La), yttrium (Y), aluminum (Al), zirconium (Zr), gadolinium (Gd) and/or the like. However, the examples are not limited thereto, and the ferroelectric layer FRL may include other ferroelectric materials.

The insulating layer AFRL may include a material without spontaneous polarization. For example, the insulating layer AFRL may include at least one of an antiferroelectric layer having no spontaneous polarization in which permanent dipoles are arranged in different directions and/or a paraelectric layer in which permanent dipoles do not exist. For example, the insulating layer AFRL may include at least one of zirconium dioxide (ZrO₂), HfₓZr₁₋ₓO₂ (x<0.5), AgNbOs, and/or the like, but the examples are not limited thereto.

The auxiliary layers LFL and LFLa each may include a material having E_{g}<4.0 eV. For example, the auxiliary pattern LF may include metal oxide having the energy band gap E_{g} lower than about 4.0 eV. For example, the auxiliary layers LFL and LFLa each may include at least one of zinc oxide (ZnO), tin oxide (SnO2), indium oxide (In2O3), titanium dioxide (TiO2), tungsten trioxide (WO3), niobium pentoxide (Nb2O5), manganese monoxide (MnO), nickel oxide (NiO), and/or the like.

For example, the ratio of the auxiliary layers LFL and LFLa in the dielectric layer DIL may be about 3% to about 10%.

According to the capacitor 113, the auxiliary layers LFL and LFLa may weaken the ferroelectricity of the dielectric layer DIL, and accordingly, deterioration in which a polarization state of the dielectric layer DIL remains in a previous polarization state without being completely restored to a state before a voltage is applied may be reduced (and/or prevented). In addition, the polarization state is maintained without being restored by the ferroelectricity of the dielectric layer DIL, thereby reducing the leakage current of the dielectric layer DIL that may occur.

In addition, according to the capacitor 113, the dielectric layer DIL includes the insulating layer AFRL that overlaps the ferroelectric layer FRL and does not have spontaneous polarization, and thus, overall ferroelectricity within the dielectric layer DIL may be reduced, thereby reducing (and/or preventing) deterioration and leakage current of the dielectric layer DIL.

The number of layers of the auxiliary layers LFL and LFLa is not limited to the number of layers in the illustrated embodiment.

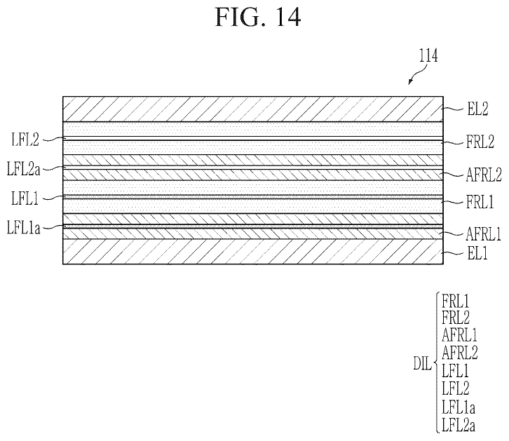

A capacitor 114 according to at least one embodiment is described with reference to FIG. 14. FIG. 14 is a cross-sectional view of a capacitor 114 according to at least one embodiment.

Referring to FIG. 14, detailed description of elements the capacitor 114 similar to (and/or the same as) the capacitors 101, 102, 103, 104, 105, 106, 107, 108, 109, 110, 111, 112, and 113 may be omitted.

Referring to FIG. 14, the capacitor 114 may include the first electrode EL1 and the second electrode EL2 facing each other and the dielectric layer DIL disposed between the first electrode EL1 and the second electrode EL2.

The first electrode EL1 and the second electrode EL2 each may include a conductive material.

A leakage current of the dielectric layer DIL may be 10⁻⁴ A/cm²≤x≤10⁻⁸ A/cm² (e.g., at 1 V). A thickness of the dielectric layer DIL may be less than or equal to about 50 Å, but the examples are not limited thereto.

The dielectric layer DIL of the capacitor 114 may include the plurality of ferroelectric layers FRL1 and FRL2, the plurality of insulating layers AFRL1 and AFRL2, the plurality of auxiliary layers LFL1 and LFL2 respectively disposed in the ferroelectric layers FRL1 and FRL2, and a plurality of auxiliary layers LFL1a and LFL2a respectively disposed in the plurality of insulating layers AFRL1 and AFRL2.

The plurality of ferroelectric layers FRL1 and FRL2 and the plurality of insulating layers AFRL1 and AFRL2 may overlap each other and be alternately disposed between the first and second electrodes EL1 and EL2 facing each other, but the examples are not limited thereto.

The plurality of ferroelectric layers FRL1 and FRL2 each may include a ferroelectric material having spontaneous polarization. In at least one embodiment, the plurality of ferroelectric layers FRL1 and FRL2 each may include at least one of hafnium oxide (HfO₂) and/or lead zirconate titanate (PbZrTi (PZT)). For example, the ferroelectric layers FRL1 and FRL2 may include hafnium oxide (HfO2) doped with at least one of silicon (Si), lanthanum (La), yttrium (Y), aluminum (Al), zirconium (Zr), gadolinium (Gd), and/or the like. However, the examples are not limited thereto, and the plurality of ferroelectric layers FRL1 and FRL2 each may include other ferroelectric materials.

The plurality of insulating layers AFRL1 and AFRL2 may include a material without spontaneous polarization. For example, the plurality of insulating layers AFRL1 and AFRL2 each may include at least one of an antiferroelectric layer having no spontaneous polarization in which permanent dipoles are arranged in different directions and/or a paraelectric layer in which permanent dipoles do not exist. For example, the plurality of insulating layers AFRL1 and AFRL2 each may include at least one of zirconium dioxide (ZrO₂), HfₓZr₁₋ₓO₂ (x<0.5), or AgNbO₃, but the examples are not limited thereto.

The plurality of auxiliary layers LFL1, LFL2, LFL1a, and LFL2a each may include a material having E_{g}<4.0 eV. For example, the auxiliary layers LFL1, LFL2, LFL1a, and LFL2a each may include metal oxide having the energy band gap E_{g} lower than about 4.0 eV. For example, the plurality of auxiliary layers LFL1, LFL2, LFL1a, and LFL2a each may include at least one of zinc oxide (ZnO), tin oxide (SnO₂), indium oxide (In₂O₃), titanium dioxide (TiO₂), tungsten trioxide (WO₃), niobium pentoxide (Nb₂O₅), manganese monoxide (MnO), nickel oxide (NiO), and/or the like.

The plurality of auxiliary layers LFL1, LFL2, LFL1a, and LFL2a may be respectively disposed inside the plurality of ferroelectric layers FRL1 and FRL2 and the plurality of insulating layers AFRL1 and AFRL2, and each may have the form of a thin film layer. A thickness of the plurality of auxiliary layers LFL1, LFL2, LFL1a, and LFL2a may be smaller than a thickness of the plurality of ferroelectric layers FRL1 and FRL2 and a thickness of the plurality of insulating layers AFRL1 and AFRL2. The plurality of ferroelectric layers FRL1 and FRL2 may be respectively disposed above and below the plurality of auxiliary layers LFL1 and LFL2, and the plurality of insulating layers AFRL1 and AFRL2 may be respectively disposed above and below the plurality of auxiliary layers LFL1a and LFL2a.

For example, a ratio of the plurality of auxiliary layers LFL1, LFL2, LFL1a, and LFL2a in the dielectric layer DIL may be about 3% to about 10%.

According to the capacitor 114, the plurality of auxiliary layers LFL1, LFL2, LFL1a, and LFL2a may weaken the ferroelectricity of the dielectric layer DIL, and accordingly, deterioration in which a polarization state of the dielectric layer DIL remains in a previous polarization state without being completely restored to a state before a voltage is applied may be reduced (and/or prevented). In addition, the polarization state is maintained without being restored by the ferroelectricity of the dielectric layer DIL, thereby reducing the leakage current of the dielectric layer DIL that may occur.

In addition, according to the capacitor 114, the dielectric layer DIL includes the plurality of insulating layers AFRL1 and AFRL2 that respectively overlap the plurality of ferroelectric layers FRL1 and FRL2 and do not have spontaneous polarization, and thus, overall ferroelectricity within the dielectric layer DIL may be reduced, thereby reducing (and/or preventing) deterioration and leakage current of the dielectric layer DIL.

The number of layers of the plurality of ferroelectric layers FRL1 and FRL2, the number of layers of the plurality of insulating layers AFRL1 and AFRL2, and the number of layers of the plurality of auxiliary layers LFL1, LFL2, LFL1a, and LFL2a are not limited to the number of layers in the illustrated embodiment.

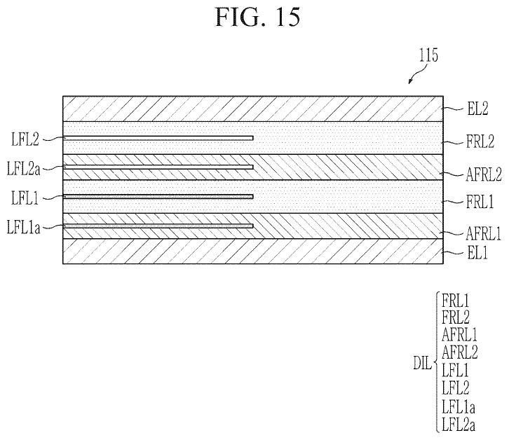

A capacitor 115 according to at least one embodiment is described with reference to FIG. 15. FIG. 15 is a cross-sectional view of a capacitor 115 according to at least one embodiment.

Referring to FIG. 15, detailed descriptions of elements of the capacitor 115 similar to (and/or the same as) the capacitors 101, 102, 103, 104, 105, 106, 107, 108, 109, 110, 111, 112, 113, and 114 may be omitted.

Referring to FIG. 15, the capacitor 115 may include the first electrode EL1 and the second electrode EL2 facing each other and the dielectric layer DIL disposed between the first electrode EL1 and the second electrode EL2.

The first electrode EL1 and the second electrode EL2 each may include a conductive material.

A leakage current of the dielectric layer DIL may be 10⁻⁴ A/cm²≤x≤10⁻⁸ A/cm² (e.g., at 1 V). A thickness of the dielectric layer DIL may be less than or equal to about 50 Å, but the examples are not limited thereto.

The dielectric layer DIL of the capacitor 115 may include the plurality of ferroelectric layers FRL1 and FRL2, the plurality of insulating layers AFRL1 and AFRL2, the plurality of auxiliary layers LFL1 and LFL2 respectively disposed in the ferroelectric layers FRL1 and FRL2, and the plurality of auxiliary layers LFL1a and LFL2a respectively disposed in the plurality of insulating layers AFRL1 and AFRL2.

The plurality of ferroelectric layers FRL1 and FRL2 and the plurality of insulating layers AFRL1 and AFRL2 may overlap each other and be alternately disposed between the first and second electrodes EL1 and EL2 facing each other, but the examples are not limited thereto.

The plurality of ferroelectric layers FRL1 and FRL2 each may include a ferroelectric material having spontaneous polarization. In at least one embodiment, the plurality of ferroelectric layers FRL1 and FRL2 each may include at least one of hafnium oxide (HfO₂) or lead zirconate titanate (PbZrTi (PZT)). For example, the ferroelectric layers FRL1 and FRL2 may include hafnium oxide (HfO₂) doped with at least one of silicon (Si), lanthanum (La), yttrium (Y), aluminum (Al), zirconium (Zr), gadolinium (Gd), and/or the like. However, the examples are not limited thereto, and the plurality of ferroelectric layers FRL1 and FRL2 each may include other ferroelectric materials.

The plurality of insulating layers AFRL1 and AFRL2 may include a material without spontaneous polarization. For example, the plurality of insulating layers AFRL1 and AFRL2 each may include at least one of an antiferroelectric layer having no spontaneous polarization in which permanent dipoles are arranged in different directions and/or a paraelectric layer in which permanent dipoles do not exist. For example, the plurality of insulating layers AFRL1 and AFRL2 each may include at least one of zirconium dioxide (ZrO₂), HfₓZr₁₋ₓO₂ (x<0.5), or AgNbO₃, but the examples are not limited thereto.

The plurality of auxiliary layers LFL1, LFL2, LFL1a, and LFL2a each may include a material having E_{g}<4.0 eV. For example, the auxiliary layers LFL1, LFL2, LFL1a, and LFL2a each may include metal oxide having the energy band gap E_{g} lower than about 4.0 eV. For example, the plurality of auxiliary layers LFL1, LFL2, LFL1a, and LFL2a each may include at least one of zinc oxide (ZnO), tin oxide (SnO2), indium oxide (In2O3), titanium dioxide (TiO2), tungsten trioxide (WO3), niobium pentoxide (Nb2O5), manganese monoxide (MnO), nickel oxide (NiO), and/or the like.

The plurality of auxiliary layers LFL1, LFL2, LFL1a, and LFL2a may be respectively inserted into a part of the plurality of ferroelectric layers FRL1 and FRL2 and a part of the plurality of insulating layers AFRL1 and AFRL2. The plurality of auxiliary layers LFL1, LFL2, LFL1a, and LFL2a each may have the form of a thin film layer and the plurality of auxiliary layers LFL1, LFL2, LFL1a, and LFL2a may respectively partially overlap the plurality of ferroelectric layers FRL1 and FRL2 and a part of the plurality of insulating layers AFRL1 and AFRL2. A planar area of the plurality of auxiliary layers LFL1, LFL2, LFL1a, and LFL2a may be smaller than a planar area of the plurality of ferroelectric layers FRL1 and FRL2 and a planar area of the plurality of insulating layers AFRL1 and AFRL2. A thickness of the plurality of auxiliary layers LFL1, LFL2, LFL1a, and LFL2a may be smaller than a thickness of the plurality of ferroelectric layers FRL1 and FRL2 and a thickness of the plurality of insulating layers AFRL1 and AFRL2. The plurality of ferroelectric layers FRL1 and FRL2 may be respectively disposed above and below the plurality of auxiliary layers LFL1 and LFL2, and the plurality of insulating layers AFRL1 and AFRL2 may be respectively disposed above and below the plurality of auxiliary layers LFL1a and LFL2a.

For example, a ratio of the plurality of auxiliary layers LFL1, LFL2, LFL1a, and LFL2a in the dielectric layer DIL may be about 3% to about 10%.

According to the capacitor 115, the plurality of auxiliary layers LFL1, LFL2, LFL1a, and LFL2a may weaken the ferroelectricity of the dielectric layer DIL, and accordingly, deterioration in which a polarization state of the dielectric layer DIL remains in a previous polarization state without being completely restored to a state before a voltage is applied may be reduced (and/or prevented). In addition, the polarization state is maintained without being restored by the ferroelectricity of the dielectric layer DIL, thereby reducing the leakage current of the dielectric layer DIL that may occur.

In addition, according to the capacitor 115, the dielectric layer DIL includes the plurality of insulating layers AFRL1 and AFRL2 that respectively overlap the plurality of ferroelectric layers FRL1 and FRL2 and do not have spontaneous polarization, and thus, overall ferroelectricity within the dielectric layer DIL may be reduced, thereby reducing (and/or preventing) deterioration and leakage current of the dielectric layer DIL.

The number of layers of the plurality of ferroelectric layers FRL1 and FRL2, the number of layers of the plurality of insulating layers AFRL1 and AFRL2, and the number of layers of the plurality of auxiliary layers LFL1, LFL2, LFL1a, and LFL2a are not limited to the number of layers in the illustrated embodiment.

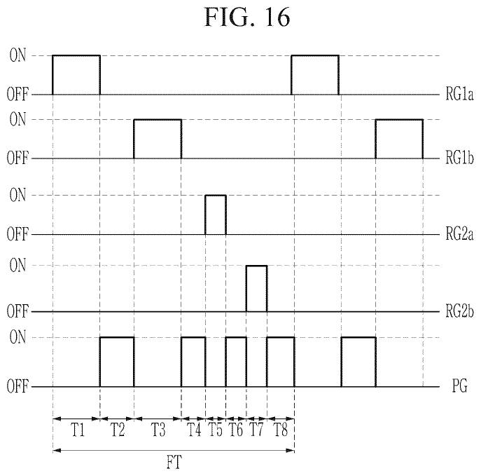

Then, a method of forming a capacitor according to at least one embodiment is described with reference to FIG. 16. FIG. 16 is a diagram for explaining a method of forming a capacitor according to at least one embodiment.

After forming the first electrode EL1, when forming the dielectric layer DIL on the first electrode EL1, an atomic layer deposition (ALD) method may be used.

Referring to FIG. 16, the ferroelectric layer FRL of an atomic layer may be formed by supplying a first process gas RG1a constituting, e.g., a precursor for the ferroelectric layer FRL of the dielectric layer DIL for a first time T1, purging the first process gas RG1a which is not deposited on a layer of the first electrode EL1 by supplying a purge gas PG for a second time T2, and then, supplying a second process gas RG1b constituting the ferroelectric layer FRL for a third time T3, and reacting the first process gas RG1a and the second process gas RG1b with each other. In at least one embodiment, the second process gas RG1b may be an oxidizer and/or a second precursor. The remaining second process gas RG1b may be purged by supplying the purge gas PG for a fourth time T4. The ferroelectric layer FRL of a desired thickness may be formed by repeating the first time T1 to the fourth time T4.

Thereafter, the auxiliary pattern LF or the auxiliary layer LFL may be formed by supplying a third process gas RG2a for the auxiliary pattern LF (or the auxiliary layer LFL) on the ferroelectric layer FRL for a fifth time T5, purging the third process gas RG2a by supplying the purge gas PG for a sixth time T6, supplying a fourth process gas RG2b for the auxiliary pattern LF or the auxiliary layer LFL for a seventh time T7, and reacting the third process gas RG2a and the fourth process gas RG2b with each other, and the remaining fourth process gas RG2b may be purged by supplying the purge gas PG for an eighth time T8.

At this time, when the fifth time T5 for supplying the third process gas RG2a and the seventh time T7 for supplying the fourth process gas RG2b are relatively short, the third process gas RG2a and the fourth process gas RG2b each may not have the form of a thin film and may be formed to be disposed only in a partial region, and accordingly, the auxiliary pattern LF may be formed. In addition, when the fifth time T5 for supplying the third process gas RG2a and the seventh time T7 for supplying the fourth process gas RG2b are relatively long, the third process gas RG2a and the fourth process gas RG2b each may be formed in the form of a thin film of the atomic layer, and accordingly, the auxiliary layer LFL may be formed. As described above, by adjusting the supply time of the third process gas RG2a and the fourth process gas RG2b constituting the auxiliary pattern LF or the auxiliary layer LFL during an atomic layer deposition process, the auxiliary pattern LF or the auxiliary layer LFL may be formed, and a ratio of the auxiliary pattern LF and the auxiliary layer LFL in the dielectric layer DIL may be adjusted.

Although not shown, by additionally supplying and purging process gases constituting the insulating layer AFRL, the insulating layer AFRL of the dielectric layer DIL may be additionally formed through the ALD method.

By repeating a process period FT including the first time T1 to the eighth time T8 described above, the dielectric layer DIL of a desired thickness may be formed.

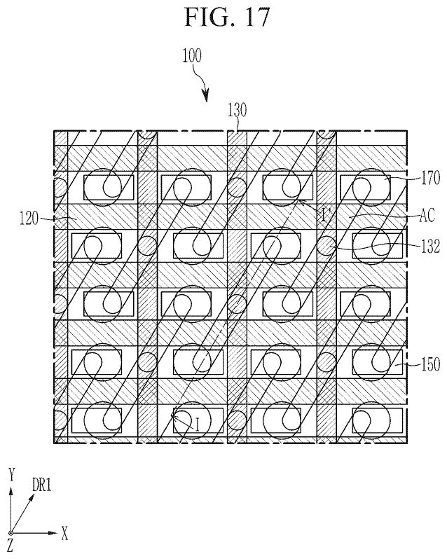

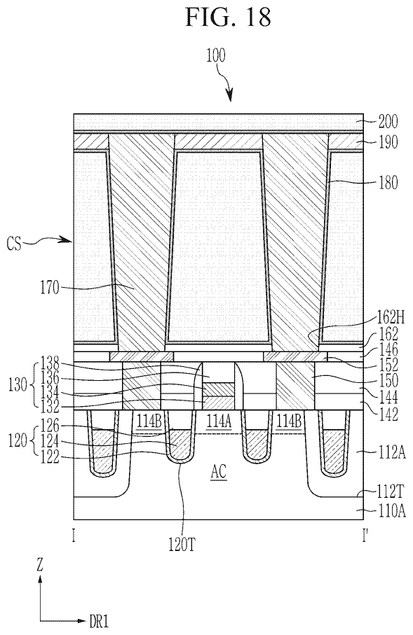

Then, a semiconductor device including a capacitor according to at least one embodiment is described with reference to FIGS. 17 and 18. FIG. 17 is a layout diagram of a semiconductor device according to at least one embodiment. FIG. 18 is a cross-sectional view taken along line I-I′ of FIG. 17.

Referring to FIGS. 17 and 18, a substrate 110A may have an active region AC defined by a device isolation layer 112A. The substrate 110A may include a semiconductor material such as Si, Ge, or SiGe, SiC, GaAs, InAs, InP, and/or the like. The substrate 110A may include a conductive region, for example, a well doped with impurities and/or a structure doped with impurities.

The device isolation layer 112A may have a shallow trench isolation (STI) structure. For example, the device isolation layer 112A may include an insulating material filling a device isolation trench 112T formed in the substrate 110A. In at least one example, the insulating material may include at least one of Fluoride Silicate Glass (FSG), Undoped Silicate Glass (USG), Boro-Phospho-Silicate Glass (BPSG), Phospho-Silicate Glass (PSG), Flowable Oxide (FOX), Plasma Enhanced Tetra-Ethyl-Ortho-Silicate (PE-TEOS), or Tonen Silazene (TOSZ), but the examples are not limited thereto and other insulating materials may be used.

The active regions AC each may have a relatively long island shape having a minor axis and a major axis on a plane. As shown in FIG. 17, the major axes of the active regions AC may be arranged in a diagonal direction DR1 parallel to an upper surface of the substrate 110A. P-type or N-type impurities may be doped in the active region AC.

The gate line trench 120T may intersect the active region AC and may be formed to a certain depth from the upper surface of the substrate 110A in a third direction (Z direction) that is a vertical direction. A part of the gate line trench 120T may extend into the device isolation layer 112A, and the part of the gate line trench 120T formed in the device isolation layer 112A may have a bottom surface disposed at a level lower than that of a part of the gate line trench 120T formed in the active region AC.

First source/drain regions 114A and second source/drain regions 114B may be disposed in an upper region of the active region AC disposed in both sides of the gate line trench 120T. The first source/drain regions 114A and the second source/drain regions 114B may be alternately disposed with the gate line trench 120T disposed therebetween.

The first source/drain region 114A and the second source/drain region 114B may be impurity regions doped with impurities having a conductivity type different from that of impurities of the doped active region AC. For example, the first source/drain region 114A and the second source/drain region 114B may be doped with N-type or P-type impurities.

A gate structure 120 may be disposed inside the gate line trench 120T. The gate structure 120 may include a gate insulating layer 122, a gate electrode 124, and a gate capping layer 126 sequentially formed on an inner wall of the gate line trench 120T.

The gate insulating layer 122 may be conformally formed on the inner wall of the gate line trench 120T to a certain thickness.

The gate insulating layer 122 may include an insulator material, such as at least one of silicon oxide, silicon nitride, silicon nitride oxide, Oxide/Nitride/Oxide (ONO), and/or a high dielectric material having a higher dielectric constant than that of silicon oxide. For example, the gate insulating layer 122 may have a dielectric constant of about 10 to about 25. In at least some examples, the gate insulating layer 122 may include at least one of HfO₂, ZrO₂, Al₂O₃, HfAlO₃, Ta₂O₃, TiO₂, and/or a combination thereof, but the examples are not limited thereto.

The gate electrode 124 may be formed to fill the gate line trench 120T from a bottom portion of the gate line trench 120T to a certain height in the third direction (Z direction) on the gate insulating layer 122.

The gate electrode 124 may include a work function adjustment layer (not shown) disposed on the gate insulating layer 122 and a buried metal layer (not shown) filling the bottom portion of the gate line trench 120T on the work function adjustment layer. For example, the work function adjustment layer may include metal, metal nitride, and/or metal carbide (such as Ti, TiN, TiAlN, TiAlC, TiAlCN, TiSiCN, Ta, TaN, TaAlN, TaAlCN, TaSiCN, etc.), and the buried metal layer may include, e.g., at least one of W, WN, TiN, TaN, and/or the like.

The gate capping layer 126 may fill the remaining part of the gate line trench 120T above the gate electrode 124. For example, the gate capping layer 126 may include, e.g., at least one of silicon oxide, silicon nitride oxide, and/or silicon nitride.

A bit line structure 130 parallel to an upper surface of the substrate 110A and extending in a second direction (Y direction) perpendicular to a first direction (X direction) may be formed on the first source/drain region 114A.

The bit line structure 130 may include a bit line contact 132, a bit line 134, a bit line capping layer 136, and a bit line spacer 138 sequentially stacked on the substrate 110A.

The bit line contact 132 may connect between the bit line 134 and the first source/drain region 114A. The bit line contact 132 may be disposed in an overlapping portion of the bit line 134 and the first source/drain region 114A. The bit line contact 132 is shown in a substantially circular shape, but is not limited thereto and a planar shape of the bit line contact 132 may be changed in various ways.

The bit line contact 132 and the bit line 134 each may include a conductive material. For example, in at least one embodiment, the bit line contact 132 may include polysilicon and the bit line 134 may include a metal material.

The bit line capping layer 136 may include an insulating material such as silicon nitride and/or silicon nitride oxide. The bit line spacer 138 may have a single layer structure or a multilayer structure including an insulating material such as silicon oxide, silicon nitride oxide, or silicon nitride.

The bit line spacer 138 may further include an air space (not shown). Selectively, a bit line interlayer (not shown) may be disposed between the bit line contact 132 and the bit line 134. The bit line interlayer may include a metal silicide such as tungsten silicide, or a metal nitride such as tungsten nitride.

FIG. 18 shows that the bit line contact 132 is formed to have a bottom surface at the same level as the upper surface of the substrate 110A, but unlike this, a recess (not shown) may be formed at a certain depth from the upper surface of the substrate 110A and the bit line contact 132 extends to the inside of the recess, so that the bottom surface of the bit line contact 132 may be formed at a lower level than the upper surface of the substrate 110A.

A first insulating layer 142 and a second insulating layer 144 may be sequentially disposed on the substrate 110A, and the bit line structure 130 may be connected to the first source/drain region 114A through the first insulating layer 142 and the second insulating layer 144.

A capacitor contact 150 may be disposed on the substrate 110A.

The capacitor contact 150 may be disposed on the second source/drain region 114B.

Side surfaces of the capacitor contact 150 may be surrounded by the first insulating layer 142 and the second insulating layer 144.

The capacitor contact 150 may include a lower contact pattern (not shown), a metal silicide layer (not shown), and an upper contact pattern (not shown) sequentially stacked on the substrate 110A, and a barrier layer (not shown) surrounding side and bottom surfaces of the upper contact pattern. The lower contact pattern may include polysilicon, and the upper contact pattern may include a metal material. The barrier layer may include a metal nitride having conductivity (e.g., a conductive metal nitride).

A third insulating layer 146, and a landing pad 152 connected to the capacitor contact 150 through the third insulating layer 146 may be disposed on the second insulating layer 144.

As shown in FIG. 18, the landing pad 152 may overlap the entire capacitor contact 150 in the third direction (Z direction) and may have a greater width than that of the capacitor contact 150.

The landing pad 152 may include a conductive material, such as at least one metal (such as ruthenium (Ru), titanium (Ti), tantalum (Ta), niobium (Nb), iridium (Ir), molybdenum (Mo), tungsten (W), etc.) and/or a conductive metal nitride (such as titanium nitride (TiN), tantalum nitride (TaN), niobium nitride (NbN), molybdenum nitride (MoN), tungsten nitride (WN), etc.). In addition, in some embodiments, the landing pad 152 may include titanium nitride (TiN).

An etch stop layer 162 may be disposed on the landing pad 152 and the third insulating layer 146. The etch stop layer 162 may include an opening 162H overlapping at least a part of the landing pad 152.

The etch stop layer 162 may include a material having an etch selectivity with respect to a mold layer including oxide (see ‘MD’ in FIG. 7). For example, the etch stop layer 162 may include at least one of silicon nitride (SiN), silicon carbon nitride (SiCN), silicon boron nitride (SiBN), silicon carbonate (SiCO), silicon nitride oxide (SiON), silicon oxide (SiO), or silicon carbonate nitride (SiOCN).

A capacitor structure CS may be disposed on the etch stop layer 162. The capacitor structure CS may include a lower electrode 170 electrically connected to the capacitor contact 150 with the landing pad 152 therebetween, a dielectric layer 180 conformally covering the lower electrode 170, and an upper electrode 200 on the dielectric layer 180.

As shown in FIG. 17, the lower electrodes 170 and the capacitor contacts 150 may be repeatedly arranged in the first direction (X direction) and the second direction (Y direction). Although not shown in FIG. 17, the landing pads 152 may overlap the lower electrodes 170 in the third direction (Z direction) and may be spaced apart in the first direction (X direction) and the second direction (Y direction) and arranged in a matrix shape. However, the examples are not limited thereto, and the capacitor contacts 150 may be repeatedly arranged in the first direction (X direction) and the second direction (Y direction), and the lower electrode 170 may be arranged in a hexagonal shape such as a honeycomb structure. In this case, the landing pad 152 may be disposed to overlap a part of the capacitor contact 150 in the third direction (Z direction) and to overlap the entire lower electrode 170 in the third direction (Z direction).

As shown in FIG. 17, the lower electrode 170 has a circular cross section on a plane, but the examples are not limited thereto, and a horizontal cross section of the lower electrode 170 may be an ellipse or various polygons and various rounded polygons such as a rectangle, a rounded rectangle, a rhombus, a trapezoid, etc.

The lower electrode 170 may be disposed on the landing pad 152, and a bottom portion of the lower electrode 170 may be disposed in the opening 162H of the etch stop layer 162. A width of the bottom portion of the lower electrode 170 may be smaller than a width of the landing pad 152, and accordingly, the entire bottom surface of the lower electrode 170 may contact the landing pad 152.

Supporters 190 may be disposed on both side surfaces of the lower electrode 170.

The supporter 190 may be disposed between the lower electrode 170 and another lower electrode 170 adjacent thereto, and may function as a support member to prevent the lower electrode 170 from falling or collapsing in a process of removing a mold layer or a process of forming the dielectric layer 180. The supporter 190 may include an insulative material, such as silicon nitride, silicon nitride oxide, silicon boron nitride (SiBN), silicon carbon nitride (SiCN), and/or the like. However, the examples are not limited thereto, and the supporter 190 may include other materials.

A dielectric layer 180 may be disposed on side and upper surfaces of the lower electrode 170. The dielectric layer 180 may extend from the side surface of the lower electrode 170 onto upper and lower surfaces of the supporter 190 and may also be disposed on the etch stop layer 162.

The dielectric layer 180 may include a layer such as the dielectric layer DIL of each of the capacitors 101, 102, 103, 104, 105, 106, 107, 108, 109, 110, 111, 112, 113, 114, and 115 according to the embodiments described above.

An upper electrode 200 covering the lower electrode 170 may be disposed on the dielectric layer 180. The upper electrode 200 may include a conductor, such as at least one of a metal (such as ruthenium (Ru), titanium (Ti), tantalum (Ta), niobium (Nb), iridium (Ir), molybdenum (Mo), tungsten (W), etc.), conductive metal nitride (such as titanium nitride (TiN), tantalum nitride (TaN), niobium nitride (NbN), molybdenum nitride (MoN), tungsten nitride (WN), etc.), and/or conductive metal oxide (such as iridium oxide (IrO₂), ruthenium oxide (RuO₂), strontium ruthenium oxide SrRuO₃), etc.). However, the material included in the upper electrode 200 is not limited thereto.

The upper electrode 200 may be formed as a single material layer or a stack structure of a plurality of material layers. For example, the upper electrode 200 may be formed as a single layer of titanium nitride (TiN) or a single layer of niobium nitride (NbN).

The upper electrode 200 may have a stack structure including a first upper electrode layer including titanium nitride (TiN) and a second upper electrode layer including niobium nitride (NbN).

The capacitor structure CS of the semiconductor device 100 shown in FIGS. 17 and 18 may include at least one of the capacitors 101, 102, 103, 104, 105, 106, 107, 108, 109, 110, 111, 112, 113, 114, and 115 according to the embodiments described above.

Accordingly, many features of the capacitors 101, 102, 103, 104, 105, 106, 107, 108, 109, 110, 111, 112, 113, 114, and 115 according to the embodiments described above are all applicable to the capacitor structure CS of the semiconductor device 100.

Although the some example embodiments of the present disclosure have been described above, the present disclosure is not limited thereto, and various modifications and implementations are possible within the scope of the claims, the detailed description of the disclosure and the accompanying drawings, and also fall within the scope of the present disclosure.

What is claimed is:

1. A capacitor comprising:
a first electrode and a second electrode spaced apart from each other; and
a dielectric layer between the first electrode and the second electrode and including a ferroelectric layer and an auxiliary portion in the ferroelectric layer,
wherein an energy band gap of the auxiliary portion is lower than about 4.0 eV.

2. The capacitor of claim 1, wherein the auxiliary portion includes a plurality of auxiliary patterns dispersed in the ferroelectric layer.

3. The capacitor of claim 2, wherein
the dielectric layer further includes an insulating layer between the ferroelectric layer and at least one of the first and second electrodes, and
the insulating layer includes at least one of an antiferroelectric layer or a paraelectric layer.

4. The capacitor of claim 2, wherein the auxiliary portion includes a plurality of first auxiliary patterns dispersed in the insulating layer.

5. The capacitor of claim 1, wherein the auxiliary portion includes an auxiliary thin film layer in the ferroelectric layer.

6. The capacitor of claim 5, wherein a thickness of the auxiliary thin film layer is less than a thickness of the ferroelectric layer.

7. The capacitor of claim 5, wherein a planar area of the auxiliary thin film layer is smaller than a planar area of the ferroelectric layer.

8. The capacitor of claim 5, wherein
the dielectric layer further includes an insulating layer between the ferroelectric layer and at least one of the first or second electrodes, and
the insulating layer includes at least one of an antiferroelectric layer or a paraelectric layer.

9. The capacitor of claim 8, wherein the dielectric layer further includes at least two auxiliary thin film layer in the insulating layer.

10. The capacitor of claim 6, wherein
the dielectric layer further includes an insulating layer between the ferroelectric layer and at least one of the first and second electrodes, and
the insulating layer includes at least one of an antiferroelectric layer or a paraelectric layer.

11. The capacitor of claim 10, wherein the dielectric layer further includes at least two auxiliary thin film layers in the insulating layer.

12. The capacitor of claim 1, wherein a ratio of the auxiliary portion of the dielectric layer to a remainder of the dielectric layer is about 3% to about 10%.

13. The capacitor of claim 12, wherein the auxiliary portion includes a metal oxide.

14. The capacitor of claim 13, wherein the auxiliary portion includes at least one of zinc oxide (ZnO), tin oxide (SnO2), indium oxide (In2O3), titanium dioxide (TiO2), tungsten trioxide (WO3), niobium pentoxide (Nb2O5), manganese monoxide (MnO), or nickel oxide (NiO).

15. The capacitor of claim 1, wherein a leakage current (x) of the dielectric layer is 10⁻⁴ A/cm²≤x≤10⁻⁸ A/cm² at 1 volt.

16. The capacitor of claim 15, wherein a thickness of the dielectric layer is greater than 0 and less than or equal to about 50 Å.

17. A semiconductor device comprising:
a substrate; and
a capacitor structure over the substrate, the capacitor structure including
a plurality of lower electrodes spaced apart from each other in a direction parallel to an upper surface of the substrate,
a supporter between the plurality of lower electrodes,
an upper electrode over the plurality of lower electrodes, and
a dielectric layer insulting the plurality of lower electrodes from the upper electrode, the dielectric layer including a ferroelectric layer and an auxiliary portion in the ferroelectric layer,
wherein an energy band gap of the auxiliary portion is less than about 4.0 eV.

18. The semiconductor device of claim 17, wherein the auxiliary portion includes a plurality of auxiliary patterns dispersed in the ferroelectric layer.

19. The semiconductor device of claim 17, wherein the auxiliary portion includes an auxiliary thin film layer in the ferroelectric layer.

20. The semiconductor device of claim 17, wherein a ratio of the auxiliary portion of the dielectric layer to a remainder of the dielectric layer is about 3% to about 10%.
